(19) United States
(12) Patent Application Publication
(10) Pub. No.: US 2025/0240106 A1
(43) Pub. Date: Jul. 24, 2025

(54) DOPPLER MEASUREMENT METHOD AND APPARATUS, AND COMMUNICATION DEVICE

(71) Applicant: VIVO MOBILE COMMUNICATION CO., LTD., Dongguan (CN)

(72) Inventors: Jian YAO, Dongguan (CN); Fei QIN, Dongguan (CN); Dajie JIANG, Dongguan (CN)

(73) Assignee: VIVO MOBILE COMMUNICATION CO., LTD., Dongguan (CN)

(21) Appl. No.: 19/174,907

(22) Filed: Apr. 9, 2025

Related U.S. Application Data
(63) Continuation of application No. PCT/CN2023/123171, filed on Oct. 7, 2023.

(30) Foreign Application Priority Data
Oct. 10, 2022 (CN) 202211237040.9

(51) Int. Cl. H04B 17/309; H03B 5/36; H04W 72/0446

(52) U.S. Cl. CPC H04B 17/309; H03B 5/366; H04W 72/0446

(57) ABSTRACT

A Doppler measurement method and apparatus, and a communication device, are provided. The Doppler measurement method includes: A first device obtains first information and second information. The first device obtains target information based on the first information and the second information. The first information is Doppler frequency shift information obtained by a third device by measuring a first signal sent by a second device. The second information is Doppler frequency shift information obtained by the second device by measuring a second signal sent by the third device. The target information is used for indicating Doppler frequency shift information between the second device and the third device. The Doppler frequency shift information is Doppler frequency shift information associated with motion of a sensing target in a channel.

### CROSS-REFERENCE TO RELATED APPLICATIONS

This application is a continuation of International Application No. PCT/CN2023/123171, filed on Oct. 7, 2023, which claims priority to Chinese Patent Application No. 202211237040.9, filed Oct. 10, 2022. The entire contents of each of the above-referenced applications are expressly incorporated herein by reference.

### TECHNICAL FIELD

This application relates to the field of communication technologies, and in particular, to a Doppler measurement method and apparatus, and a communication device.

### BACKGROUND

In the related art, frequency shift information calculated based on a received signal not only includes a Doppler frequency shift brought by channel mobility, but also includes a receiver-transmitter clock offset. For communication services, the Doppler frequency shift and the receiver-transmitter clock offset usually do not need to be distinguished, and only frequency shift compensation needs to be performed on the received signal as a whole, to meet demodulation performance. However, for sensing services, Doppler information of a channel usually needs to be obtained, and a dynamic target in an environment needs to be detected based on this. However, no specific solution on how to accurately obtain Doppler frequency shift information of a channel is provided in the related art.

### SUMMARY

Embodiments of this application provide a Doppler measurement method and apparatus, and a communication device.

According to a first aspect, a Doppler measurement method is provided, including:

A first device obtains first information and second information.

The first device obtains target information based on the first information and the second information.

The first information is Doppler frequency shift information obtained by a third device by measuring a first signal sent by a second device. The second information is Doppler frequency shift information obtained by the second device by measuring a second signal sent by the third device. The target information is used for indicating Doppler frequency shift information between the second device and the third device. The Doppler frequency shift information is Doppler frequency shift information associated with motion of a sensing target in a channel.

According to a second aspect, a Doppler measurement method is provided, including:

A third device obtains a first signal sent by a second device.

The third device obtains first information based on the first signal, and sends the first information to a first device.

The third device sends a second signal to the second device. The second signal is used for obtaining second information.

The first information and the second information are used for obtaining target information. The first information is Doppler frequency shift information obtained by the third device by measuring the first signal sent by the second device. The second information is Doppler frequency shift information obtained by the second device by measuring the second signal sent by the third device. The target information is used for indicating Doppler frequency shift information between the second device and the third device. The Doppler frequency shift information is Doppler frequency shift information associated with motion of a sensing target in a channel.

According to a third aspect, a Doppler measurement method is provided, including:

A second device sends a first signal to a third device. The first signal is used for obtaining first information.

The second device obtains a second signal sent by the third device.

The second device obtains second information based on the second signal, and sends the second information to a third device. The first information and the second information are used for obtaining target information.

The first information is Doppler frequency shift information obtained by a third device by measuring a first signal sent by a second device. The second information is Doppler frequency shift information obtained by the second device by measuring a second signal sent by the third device. The target information is used for indicating Doppler frequency shift information between the second device and the third device. The Doppler frequency shift information is Doppler frequency shift information associated with motion of a sensing target in a channel.

According to a fourth aspect, a Doppler measurement apparatus is provided, applied to a first device, and including:

a first obtaining module, configured to obtain first information and second information; and

a second obtaining module, configured to obtain target information based on the first information and the second information.

The first information is Doppler frequency shift information obtained by a third device by measuring a first signal sent by a second device. The second information is Doppler frequency shift information obtained by the second device by measuring a second signal sent by the third device. The target information is used for indicating Doppler frequency shift information between the second device and the third device. The Doppler frequency shift information is Doppler frequency shift information associated with motion of a sensing target in a channel.

According to a fifth aspect, a Doppler measurement apparatus is provided, applied to a third device, and including:
a third obtaining module, configured to obtain a first signal sent by a second device;
a first processing module, configured to obtain first information based on the first signal, and send the first information to a first device; and
a first sending module, configured to send a second signal to the second device. The second signal is used for obtaining second information.

The first information and the second information are used for obtaining target information. The first information is Doppler frequency shift information obtained by the third device by measuring the first signal sent by the second device. The second information is Doppler frequency shift information obtained by the second device by measuring the second signal sent by the third device. The target information is used for indicating Doppler frequency shift information between the second device and the third device. The Doppler frequency shift information is Doppler frequency shift information associated with motion of a sensing target in a channel.

According to a sixth aspect, a Doppler measurement apparatus is provided, applied to a second device, and including:
a second sending module, configured to send a first signal to a third device, where the first signal is used for obtaining first information;
a fourth obtaining module, configured to obtain a second signal sent by the third device; and
a second processing module, configured to obtain second information based on the second signal, and send the second information to the third device, where the first information and the second information are used for obtaining target information.

The first information is Doppler frequency shift information obtained by a third device by measuring a first signal sent by a second device. The second information is Doppler frequency shift information obtained by the second device by measuring a second signal sent by the third device. The target information is used for indicating Doppler frequency shift information between the second device and the third device. The Doppler frequency shift information is Doppler frequency shift information associated with motion of a sensing target in a channel.

According to a seventh aspect, a terminal (a third device) is provided. The terminal includes a processor and a memory. The memory stores a program or an instruction executable in the processor. The program or the instruction, when executed by the processor, implements the steps of the method described in the second aspect.

According to an eighth aspect, a terminal (a third device) is provided, including a processor and a communication interface. The communication interface is configured to obtain a first signal sent by a second device. The processor is configured to obtain first information based on the first signal, and send the first information to a first device through the communication interface. The communication interface is configured to send a second signal to the second device. The second signal is used for obtaining second information.

The first information and the second information are used for obtaining target information. The first information is Doppler frequency shift information obtained by the third device by measuring the first signal sent by the second device. The second information is Doppler frequency shift information obtained by the second device by measuring the second signal sent by the third device. The target information is used for indicating Doppler frequency shift information between the second device and the third device. The Doppler frequency shift information is Doppler frequency shift information associated with motion of a sensing target in a channel.

According to a ninth aspect, a network side device (a first device or a second device) is provided. The network side device includes a processor and a memory. The memory stores a program or an instruction executable in the processor. The program or the instruction, when executed by the processor, implements the steps of the method described in the first aspect or the third aspect.

According to a tenth aspect, a network side device is provided, including a processor and a communication interface. The communication interface is configured to obtain first information and second information. The processor is configured to obtain target information based on the first information and the second information.

The first information is Doppler frequency shift information obtained by a third device by measuring a first signal sent by a second device. The second information is Doppler frequency shift information obtained by the second device by measuring a second signal sent by the third device. The target information is used for indicating Doppler frequency shift information between the second device and the third device. The Doppler frequency shift information is Doppler frequency shift information associated with motion of a sensing target in a channel.

Alternatively, the communication interface is configured to send a first signal to the third device, where the first signal is used for obtaining first information, and obtain the second signal sent by the third device. The processor is configured to obtain second information based on the second signal, and sends the second information to the third device through the communication interface. The first information and the second information are used for obtaining target information.

The first information is Doppler frequency shift information obtained by a third device by measuring a first signal sent by a second device. The second information is Doppler frequency shift information obtained by the second device by measuring a second signal sent by the third device. The target information is used for indicating Doppler frequency shift information between the second device and the third device. The Doppler frequency shift information is Doppler frequency shift information associated with motion of a sensing target in a channel.

According to an eleventh aspect, a Doppler measurement system is provided, including a first device, a second device, and a third device. The first device may be configured to perform the steps of the method described in the first aspect. The second device may be configured to perform the steps of the method described in the third aspect. The third device may be configured to perform the steps of the method described in the second aspect.

According to a twelfth aspect, a readable storage medium is provided. The readable storage medium stores a program or an instruction. The program or the instruction, when executed by a processor, implements the steps of the method described in the first aspect, or implements the steps of the method described in the second aspect or the third aspect.

According to a thirteenth aspect, a chip is provided. The chip includes a processor and a communication interface. The communication interface is coupled to the processor. The processor is configured to run a program or an instruction to implement the method described in the first aspect or implement the method described in the second aspect or the third aspect.

According to a fourteenth aspect, a computer program/program product is provided. The computer program/program product is stored in a storage medium. The computer program/program product is executed by at least one processor to implement the steps of the method described in the first aspect, the second aspect, or the third aspect.

In embodiments of this application, a first device obtains first information and second information. The first device obtains target information based on the first information and the second information. The first information is Doppler frequency shift information obtained by a third device by measuring a first signal sent by a second device. The second information is Doppler frequency shift information obtained by the second device by measuring a second signal sent by the third device. The target information is used for indicating Doppler frequency shift information between the second device and the third device. The foregoing first information includes a clock frequency offset of a transceiver device, the second information also includes the clock frequency offset of the transceiver device, and the transceiver devices corresponding to the first information and the second information are opposite.

### BRIEF DESCRIPTION OF THE DRAWINGS

FIG. 1 is a structural diagram of a communication system to which an embodiment of this application may be applied;

FIG. 2 is a first flowchart of a Doppler measurement method according to an embodiment of this application;

FIG. 3 is a first schematic diagram of a first signal and a second signal according to an embodiment of this application;

FIG. 4 is a second schematic diagram of a first signal and a second signal according to an embodiment of this application;

FIG. 5 is a schematic diagram of calculation of a Signal to Noise Ratio (SNR) of a one-dimensional graph according to an embodiment of this application;

FIG. 6 is a second flowchart of a Doppler measurement method according to an embodiment of this application;

FIG. 7 is a third flowchart of a Doppler measurement method according to an embodiment of this application;

FIG. 8 is a first block diagram of modules of a Doppler measurement apparatus according to an embodiment of this application;

FIG. 9 is a second block diagram of modules of a Doppler measurement apparatus according to an embodiment of this application;

FIG. 10 is a third block diagram of modules of a Doppler measurement apparatus according to an embodiment of this application;

FIG. 11 is a block diagram of a communication device according to an embodiment of this application;

FIG. 12 is a block diagram of a terminal according to an embodiment of this application;

FIG. 13 is a first block diagram of a network side device according to an embodiment of this application; and

FIG. 14 is a second block diagram of a network side device according to an embodiment of this application.

### DETAILED DESCRIPTION

Embodiments of this application are described below with reference to accompanying drawings in embodiments of this application. Apparently, the described embodiments are merely some rather than all embodiments of this application. All other embodiments obtained by a person of ordinary skill in the art based on embodiments of this application fall within the protection scope of this application.

Terms “first,” “second,” and the like in the specification and the claims of this application are used to distinguish between similar objects, and are not used to describe a specific order or sequence. It should be understood that the terms used in this way may be transposed where appropriate, so that embodiments of this application may be implemented in a sequence other than those illustrated or described herein. In addition, objects defined by “first” and “second” are generally of the same class and do not limit a quantity of objects. For example, one or more first objects may be arranged. In addition, “and/or” in the specification and the claims indicates at least one of connected objects, and a character “/” generally indicates an “or” relationship between associated objects.

It should be noted that, the technology described in embodiments of this application may be applied to a Long Term Evolution (LTE)/LTE-Advanced (LTE-A) system, and may be further applied to another wireless communication system, such as a Code Division Multiple Access (CDMA) system, a Time Division Multiple Access (TDMA) system, a Frequency Division Multiple Access (FDMA) system, an Orthogonal Frequency Division Multiple Access (OFDMA) system, a Single-Carrier Frequency Division Multiple Access (SC-FDMA) system, and another system. Terms “system” and “network” in embodiments of this application are usually interchangeably used, and the described technology may be applied to both the system and the radio technology mentioned above, or may be applied to another system and radio technology. A New Radio (NR) system is described below as an example, and the term NR is used in most of the following description. Nevertheless, the technologies may also be applied to an application other than an application of the NR system, such as a 6th Generation (6G) communication system.

FIG. 1 is a block diagram showing a wireless communication system to which an embodiment of this application may be applied. The wireless communication system includes a terminal 11 and a network side device 12. The terminal 11 may be a terminal side device such as a mobile phone, a tablet computer, a laptop computer, which is also referred to as a notebook computer, a Personal Digital Assistant (PDA), a palm computer, a netbook, an Ultra-Mobile Personal Computer (UMPC), a Mobile Internet Device (MID), an Augmented Reality (AR)/Virtual Reality (VR) device, a robot, a wearable device, an on-board device (Vehicle User Equipment (VUE)), a Pedestrian User Equipment (PUE), smart home (a home device with a wireless communication capability, such as a refrigerator, a television, a washing machine, or furniture), a game console, a personal computer (PC), a teller machine, or a self-service machine. The wearable device includes a smart watch, a smart bracelet, a smart headset, smart glasses, smart jewelry (a smart bracelet, a smart chain bracelet, a smart ring, a smart necklace, a smart ankle bangle, a smart ankle chain, and the like), a smart wristband, smart clothing, and the like. It should be noted that a specific type of the terminal 11 is not limited in embodiments of this application. The network side device 12 may include an access network device or a core network device. The access network device may also be referred to as a wireless access network device, a Radio Access Network (RAN), a wireless access network function, or a wireless access network unit. The access network device may include a base station, a Wireless Local Area Network (WLAN) access point, a Wi-Fi node, or the like. The base station may be referred to as a NodeB, an evolved NodeB (eNB), an access point, a Base Transceiver Station (BTS), a radio base station, a radio transceiver, a Basic Service Set (BSS), an Extended Service Set (ESS), a household NodeB, a household evolved NodeB, a Transmission Reception Point (TRP), or another appropriate term in the field, as long as the same technical effect is achieved. The base station is not limited to a specific technical term. It should be noted that, in embodiments of this application, only a base station in the NR system is used as an example, but a specific type of the base station is not limited. The core network device may include but is not limited to at least one of the following: a core network node, a core network function, a Mobility Management Entity (MME), an Access and Mobility Management Function (AMF), a Session Management Function (SMF), a User Plane Function (UPF), a Policy Control Function (PCF), a Policy and Charging Rules Function (PCRF), an Edge Application Server Discovery Function (EASDF), Unified Data Management (UDM), a Unified Data Repository (UDR), a Home Subscriber Server (HSS), a Centralized Network Configuration (CNC), a Network Repository Function (NRF), a Network Exposure Function (NEF), a Local NEF (L-NEF), a Binding Support Function (BSF), an Application Function (AF), and the like. It should be noted that in embodiments of this application, only a core network device in the NR system is used as an example, and a specific type of the core network device is not limited.

To enable a technical person of the art to better understand embodiments of this application, the following description is provided first.

A future mobile communication system, such as a Beyond 5th Generation (B5G) system or a 6G system, is to have not only a communication capability but also a sensing capability. The sensing capability is an ability of one or more devices to sense information such as an orientation, a distance, or a speed of a target object or to detect, track, recognize, or form an image of a target object, an event, an environment, or the like by sending and receiving a wireless signal. With deployment of small base stations with a high bandwidth capability such as millimeter waves and terahertz in the 6G network in the future, sensing resolution is significantly improved compared with that of centimeter waves, so that the 6G network can provide more refined sensing services. Typical sensing functions and application scenarios are shown in Table 1.

TABLE 1

| Communication and | | |
|---|---|---|
| sensing category | Sensing function | Application scenario |
| Macro sensing | Weather condition, air quality, | Meteorology, agriculture, and life |
| | and the like | services |
| | Traffic flow (intersection) and | Intelligent transportation and |
| | pedestrian flow (subway entrance) | commercial service |
| | Target tracking, ranging, speed | Numerous application scenarios of |
| | measurement, contour, and the like | conventional radar |
| | Environment reconstruction | Intelligent driving and navigation |
| | | (automobiles/unmanned aerial |
| | | vehicles), a smart city (a three- |
| | | dimensional (3D) map), and |
| | | network planning and optimization |
| Refined sensing | Action/posture/expression | Intelligent interaction, game, and |
| | recognition | smart home through a smartphone |
| | Heartbeat/breathing, or the like | Health and healthcare |
| | Imaging, material detection, | Security check, industry, |
| | composition analysis, and the like | biomedicine, and the like |

Integrated sensing and communication means realizing an integrated design of communication and sensing functions through spectrum sharing and hardware sharing in a same system. During information transmission, a system can sense information such as an orientation, a distance, and a speed, and detect, track, and recognize a target object or event. A communication system and a sensing system complement each other, to realize overall performance improvement and better service experience.

Integrated radar and communication is a typical communication-sensing fused application. In the past, a radar system and a communication system were strictly distinguished from each other due to different research objects and focuses, which are researched separately in most scenarios. In fact, the radar system and the communication system are both typical information transmission, obtaining, processing, and exchange manners, and have many similarities in terms of operating principle, system architecture, and band. The integrated design of radar and communication has high feasibility, which is mainly reflected in the following aspects: First, the communication system and the sensing system are both based on the electromagnetic wave theory, which complete information obtaining and transmission through transmission and receiving of electromagnetic waves. The communication system and the sensing system both have structures such as an antenna, a transmitter end, a receiver end, and a signal processor, with significant overlapping in hardware resource. With development of technologies, an increasing overlap exists between the two in the operating band. In addition, similarities exist in key technologies such as signal modulation, reception detection, and waveform design. The fusion of the communication system and the radar system can bring many advantages, such as reduced costs, reduced sizes, reduced power consumption, improved spectrum efficiency, and reduced mutual interference, thereby improving overall performance of the system.

Based on a difference between a sending node and a receiving node of a sensing signal, the following 6 sensing links are provided. It should be noted that for each sensing link described below, a sending node and a receiving node are used as an example. In an actual system, different sensing links may be selected based on different sensing requirements. Each sensing link may have one or more sending nodes and receiving nodes, and an actual sensing system may include a plurality of different sensing links.

1) Echo sensing through a base station. In this way, a base station sends a sensing signal and obtains a sensing result by receiving an echo of the sensing signal.

2) Radio sensing between base stations. In this case, a base station 2 receives a sensing signal sent by a base station 1 to obtain a sensing result.

3) Uplink radio sensing. In this case, a base station receives a sensing signal sent by a user equipment (UE) to obtain a sensing result.

4) Downlink radio sensing. In this case, a UE receives a sensing signal sent by a base station to obtain a sensing result.

5) Echo sensing through a terminal. In this case, a UE sends a sensing signal and obtains a sensing result by receiving an echo of the sensing signal.

6) Sidelink sensing between terminals. For example, a UE 2 receives a sensing signal sent by a UE 1 to obtain a sensing result.

In an actual process of performing a sensing service, a non-ideal hardware factor usually exists, which affects accuracy of sensing measurement. Especially in the foregoing 6 manners where transceiver devices are different, a corresponding carrier wave needs to be generated on each of a sending terminal and a receiving terminal to complete corresponding up-conversion and down-conversion operations. The sending terminal needs to transfer a sending signal to a specific frequency point through up-conversion for sending, and the receiving terminal needs to downconvert a received signal to a baseband to facilitate subsequent processing. A complete consistency between a receiver clock and a transmitter clock generally cannot be ensured, and a receiver crystal oscillator and a transmitter crystal oscillator have respective accuracies, causing a deviation between a frequency of a carrier signal generated by a system and an ideal frequency. The deviation is one of main sources of a carrier frequency shift of the received signal. In addition, channel mobility may also cause a carrier frequency shift.

It may be learned from the foregoing description that frequency shift information calculated based on the received signal not only includes a Doppler frequency shift brought by channel mobility, but also includes a receiver-transmitter clock offset. For communication services, the Doppler frequency shift and the receiver-transmitter clock offset usually do not need to be distinguished, and only frequency shift compensation needs to be performed on the received signal as a whole, to meet demodulation performance. However, for sensing services, Doppler information of a channel usually needs to be obtained, thereby detecting a dynamic target in an environment. The impact of the receiver-transmitter clock offset on Doppler measurement is specifically explained as follows.

It is assumed that no receiver-transmitter frequency offset exists, a sending signal is s(t), H reflectors are present in a channel, and a receiving terminal obtains a baseband reception signal through down-conversion as follows:

$$r ( t ) = {\sum }_{h = 0}^{H - 1} {b}_{h} s ( t - {τ}_{h} ) {e}^{j 2 π {f}_{D , h} t} {e}^{j {\tilde{φ}}_{h}} + \tilde{z} ( t ) ,$$

where \tilde{φ}ₕ represents a random phase rotation, \tilde{z}(t) is white Gaussian noise, bₕ is an amplitude attenuation factor, f_{D,h} is Doppler frequency shift information corresponding to an h^{th} reflector in the channel, and τₕ is a latency corresponding to the h^{th} reflector.

In this case, the receiving terminal may obtain the Doppler frequency shift information of the channel by detecting a phase change (time domain Fast Fourier Transform (FFT)) of a time domain dimension. However, in an actual system, a complete consistency between a receiver clock and a transmitter clock cannot be ensured, that is, a receiver-transmitter frequency offset exists. It is assumed that a carrier frequency of the sending terminal is ft, a carrier frequency of the receiving terminal is fr, and ft is not equal to fr.

A residual frequency difference ft−fr exists in the receiving terminal after down-conversion, that is, a baseband reception signal is:

$$r ( t ) = {\sum }_{h = 0}^{H - 1} {b}_{h} s ( t - {τ}_{h} ) {e}^{j 2 π {f}_{D , h} t} {e}^{j 2 π ( {f}_{t} - {f}_{r} ) t} {e}^{j {\tilde{φ}}_{h}} + \tilde{z} ( t ) .$$

In this case, the receiving terminal cannot obtain Doppler frequency shift information of an original channel by detecting a phase change of a time domain dimension, for example, performing a time domain FFT operation.

A Doppler measurement method provided in embodiments of this application is described in detail below through some embodiments and application scenarios with reference to the accompanying drawings.

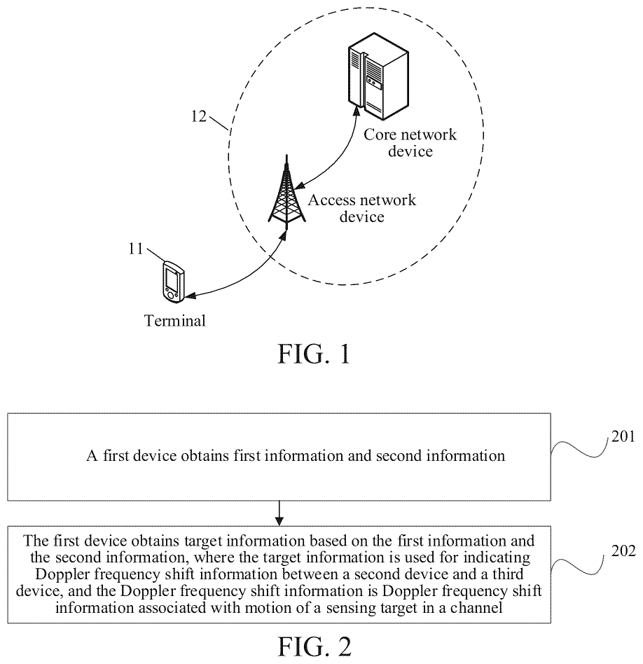

As shown in FIG. 2, an embodiment of this application provides a Doppler measurement method, including the following steps.

Step 201: A first device obtains first information and second information.

The first information is Doppler frequency shift information obtained by a third device by measuring a first signal sent by a second device. The second information is Doppler frequency shift information obtained by the second device by measuring a second signal sent by the third device.

In this step, the first device obtains the first information sent by the third device, and obtains the second information sent by the second device.

The first device in this application may be a core network sensing network function device, the second device may be a network side device such as a base station, and the third device may be specifically a terminal.

In embodiments of this application, the network side device sends the first signal through a downlink slot, and the terminal sends the second signal through an uplink slot.

Step 202: The first device obtains target information based on the first information and the second information, where the target information is used for indicating Doppler frequency shift information between the second device and the third device, and the Doppler frequency shift information is Doppler frequency shift information associated with motion of a sensing target in a channel. In other words, the Doppler frequency shift information is Doppler frequency shift information caused by the motion of the sensing target in the channel.

In some embodiments, the receiver-transmitter clock offset is counteracted through a preset algorithm (for example, two Doppler measurement results are added and then divided by 2) based on the foregoing first information and second information, to obtain target information, that is, the Doppler frequency shift information between the second device and the third device.

In embodiments of this application, the second device sends the first signal to the third device, and the third device performs measurement to obtain and send first information to the first device. The third device sends the second signal to the second device, and the second device performs measurement on the second signal to obtain and send second information to the first device. The first device obtains the target information based on the first information and the second information, specifically including the following.

In an implementation, a sending signal s(t) (that is, a first signal) of the second device through up-conversion is represented as:

s1(t)=s(t)e^{j2πf}^{ₜ}^{t}

The received signal after down-conversion of the received first signal by the third device is represented as:

$$r 1 ( t ) = {\sum }_{h = 0}^{H - 1} {b}_{h} s ( t - {τ}_{h} ) {e}^{j 2 π {f}_{D , h} t} {e}^{j 2 π ( {f}_{t} - {f}_{r} ) t} {e}^{j {\tilde{φ}}_{h}} + \tilde{z} ( t ) .$$

The third device obtains first information through calculation based on r(t):

$$\begin{matrix}{f}_{D 1 , h} = {f}_{D , h} + ( {f}_{t} - {f}_{r} ) & h = 0 , 1 , ⋯ , H - 1\end{matrix} .$$

The third device sends the first information to the first device, and sends a second signal s2(t) to the second device:

s2(t)=s(t)e^{j2πf}^{ᵣ}^{t}

The second device receives s2(t) and performs down-conversion to obtain:

$$r 2 ( t ) = {\sum }_{h = 0}^{H - 1} {b}_{h} s 2 ( t - {τ}_{h} ) {e}^{j 2 π {f}_{D , h} t} {e}^{j 2 π ( {f}_{t} - {f}_{r} ) t} {e}^{j {\tilde{φ}}_{h}} + \tilde{z} ( t ) .$$

The second device obtains second information based on r2(t), and sends the second information to the first device:

$$\begin{matrix}{f}_{D 2 , h} = {f}_{D , h} + ( {f}_{r} - {f}_{t} ) & h = 0 , 1 , ⋯ , H - 1\end{matrix} .$$

The target information is obtained based on the first information and the second information:

$${f}_{D , h} = \frac{{f}_{D 1 , h} + {f}_{D 2 , h}}{2} \qquad h = 0 , 1 , ⋯ , H - 1.$$

In other words, after the second device and the third device send measurement signals bidirectionally to perform Doppler measurement, the impact of a receiver-transmitter clock frequency offset is counteracted (that is, fᵣ−fₜ is counteracted) when two Doppler measurement results (the first information and the second information) are combined, and the obtained target information is not affected by the receiver-transmitter clock frequency shift.

It should be noted that the Doppler frequency shift information in embodiments of this application includes Doppler frequency shift information caused by motion of at least one sensing target in the channel. In an implementation, the foregoing sensing target is at least one of the foregoing reflectors.

In embodiments of this application, the first device obtains the first information and the second information. The first device obtains target information based on the first information and the second information. The first information is Doppler frequency shift information obtained by a third device by measuring a first signal sent by a second device. The second information is Doppler frequency shift information obtained by the second device by measuring a second signal sent by the third device. The target information is used for indicating Doppler frequency shift information between the second device and the third device. The foregoing first information includes a clock frequency offset of a transceiver device, the second information also includes the clock frequency offset of the transceiver device, and the transceiver devices corresponding to the first information and the second information are opposite. Therefore, the receiver-transmitter clock frequency offset can be counteracted through a certain algorithm based on the foregoing first information and second information, to accurately obtain Doppler frequency shift information between the second device and the third device, thereby improving accuracy of Doppler measurement.

In some embodiments, the first signal and the second signal have a same time domain resource format.

The time domain resource format includes a time domain resource length and a time domain resource interval.

Herein, the first signal and the second signal have the same time domain resource format, so as to ensure that the first signal and the second signal have the same Doppler measurement performance.

In some embodiments, the first signal and the second signal have the same time domain resource length, and/or the first signal and the second signal have the same time domain resource interval.

In some embodiments, a time domain resource length of the first signal and a time domain resource length of the second signal are associated with a Doppler resolution; and/or a time domain resource interval of the first signal and a time domain resource interval of the second signal are associated with a maximum unambiguous Doppler frequency shift.

In embodiments of this application, a time domain resource length T of the first signal and the second signal meets the following equation:

$$T \geq 1 / Δ {f}_{d}$$

where T represents the time domain resource length, and Δf_{d} represents a Doppler resolution.

In embodiments of this application, the time domain resource interval of the first signal and a time domain resource interval ΔT of the second signal meet the following equation:

$$Δ T \leq 1 / {f}_{d max} .$$

If a speed and a direction of motion of a target in the channel are not considered, ΔT≤1/f_{d max} is met, and if the speed and the direction of motion of the target in the channel are considered, ΔT≤1/(2|f_{d max}|) is met, where ΔT is the time domain resource interval, and f_{d max} is the maximum unambiguous Doppler frequency shift.

It should be noted that calculation of Doppler at the receiving terminal needs to be based on a signal time domain phase change, that is, 2πf_{d}ΔT=θ, where θ is a time sensing signal time domain phase change at ΔT. When the speed and the direction are not considered, to ensure that Doppler ambiguity does not occur, θ−2πf_{d}ΔT≤2π needs to be met. In other words, a relationship between the maximum unambiguous Doppler frequency shift and a signal time domain interval is ΔT≤1(f_{d max}), and a relationship between a maximum unambiguous speed and the maximum unambiguous Doppler frequency shift is vₘₐₓ=f_{d max}c/2f_{c}. Therefore, a relationship between the maximum unambiguous speed and the signal time domain interval is ΔT≤c/(2f_{c}vₙₐₓ). When the speed and the direction are considered, to ensure that the Doppler ambiguity does not occur, θ=|2πf_{d}ΔT|≤π needs to be met. In other words, a relationship between the maximum unambiguous Doppler frequency shift and a sensing signal time domain interval is ΔT₁≤1/(2|f_{d max}|), and a relationship between the maximum unambiguous speed and the sensing signal time domain interval is ΔT≤c/(4f_{c}|vₘₐₓ|).

In some embodiments, the Doppler resolution and the maximum unambiguous Doppler frequency shift are obtained based on a sensing requirement. The sensing requirement is obtained by the first device.

In some embodiments, the sensing requirement includes at least one of the following:

a) Sensing of a service: The service is classified or embodied by type as a specific service, for example, environment reconstruction, breathing or heartbeat detection, positioning or trajectory tracking, motion recognition, weather monitoring, or radar ranging/speed measurement/angle measurement.

b) Sensing target area: The target area refers to a position area where a sensing object may exist, or a position area where imaging or environment reconstruction needs to be performed.

c) Type of a sensing object: The sensing object is classified based on possible motion characteristics of the sensing objects, and each sensing object type includes information such as a motion speed, a motion acceleration, and a typical RCS of a typical sensing object.

d) Sensing QoS: It is a performance indicator for sensing a sensing target area or a sensing object, including at least one of the following:
(1) a sensing resolution (which may be further classified into a ranging resolution, an angle measurement resolution, a speed measurement resolution, an imaging resolution, and the like);
(2) a sensing precision (which may be further classified into a ranging precision, an angle measurement precision, a speed measurement precision, a positioning precision, and the like);
(3) a sensing range (which may be further classified into a ranging range, a speed measurement range, an angle measurement range, an imaging range, and the like);
(4) a sensing latency (which is a time interval between sending of a sensing signal and obtaining of a sensing result, or a time interval between initiation of a sensing requirement and obtaining of a sensing result);
(5) a sensing update rate (which is a time interval between two adjacent executions of sensing and obtaining of sensing results);
(6) a detection probability (which is a probability that a sensing object is correctly detected in a case that the sensing object exists);
(7) a false alarm probability (which is a probability that a sensing target is falsely detected in a case that the sensing object does not exist); and
(8) a maximum quantity of targets that may be sensed.

In some embodiments, before the obtaining, by a first device, first information and second information, the method further includes:

The first device sends a first request to the second device, and sends a second request to the third device. The first request is used for requesting a second device to perform Doppler measurement, and the second request is used for requesting the third device to perform Doppler measurement.

The first device obtains a first response sent by the second device and a second response sent by the third device.

The first response is used for indicating that the second device participates in the Doppler measurement, or used for indicating that the second device refuses to participate in the Doppler measurement and/or a reason for refusing to participate in the Doppler measurement.

The second response is used for indicating that the third device participates in the Doppler measurement, or used for indicating that the third device refuses to participate in the Doppler measurement and/or a reason for refusing to participate in the Doppler measurement.

The first information is obtained in a case that the first response indicates that the third device participates in the Doppler measurement.

The second information is obtained in a case that the second response indicates that the second device participates in the Doppler measurement.

In some embodiments, the first request carries identification information of the third device, or carries identification information of the second device and the third device. The second request carries identification information of the second device, or carries the identification information of the second device and the third device. The first device may simultaneously send the foregoing first request and second request, or may send the foregoing first request and second request successively.

After receiving the foregoing request, the second device and the third device may determine, based on at least one of mobility information, position information, battery status information, and sending resource information, whether to participate in the Doppler measurement, and send response information.

It should be noted that if the first response is used for indicating that the second device refuses to participate in the Doppler measurement and/or a reason for refusing to participate in the Doppler measurement, the first device reselects the second device.

If the second response is used for indicating that the third device refuses to participate in the Doppler measurement and/or a reason for refusing to participate in the Doppler measurement, the first device reselects the third device.

In some embodiments, the method further includes:
obtaining device information sent by a candidate second device and device information sent by a candidate third device; and
determining the second device and the third device based on the device information.

The device information includes at least one of the following:
a frequency tolerance (also referred to as a clock frequency error) or frequency stability information, which specifically refers to a change amount relative to a nominal clock frequency, and may be expressed in ppm;
position information;
mobility information;
battery status information;
temperature information;
available resource information, where the available resource information includes a sending resource and/or a receiving resource;
fault status information;
a supported sensing measurement manner, such as loop-back, and sending by A and receiving by B;
a supported sensing service;
a supported sensing measurement quantity;
a supported sensing waveform or communication waveform;
an operating band;
an operating bandwidth;
a transmission power; and
antenna configuration information.

In embodiments of this application, the first device obtains the foregoing device information, selects a second device and a third device based on the foregoing device information, and/or determines, based on the foregoing device information, a calculation manner of obtaining target information based on first information and second information.

In some embodiments, the first device sends an information obtaining request to the second device and/or the third device, and the second device and/or the third device feeds back device information to the first device based on the information obtaining request.

In some embodiments, the method in embodiments of this application further includes:

The first device sends configuration information of the first signal to the second device and the third device.

Herein, the first device sends the configuration information of the first signal to the second device, so that the second device sends the first signal based on the configuration information of the first signal. The first device sends the configuration information of the first signal to the third device, so that the third device receives the first signal based on the configuration information of the first signal.

The configuration information of the first signal includes at least one of the following: configuration identification information;
a waveform;
a subcarrier interval;
a guard interval;
a frequency domain start position;
a frequency domain resource length;
a frequency domain resource interval;
a time domain start position;
a time domain resource length;
a time domain resource interval;
a signal power;
sequence information; and
a signal direction.

The configuration identification information is used for distinguishing between signal configuration information of different first signals.

The foregoing waveform may be an Orthogonal Frequency Division Multiplexing (OFDM) waveform, a Single-Carrier Frequency-Division Multiple Access (SC-FDMA) waveform, an Orthogonal Time Frequency Space (OTFS) waveform, a Frequency Modulated Continuous Wave (FMCW) waveform, a pulse signal waveform, and the like.

The foregoing subcarrier interval may be a subcarrier interval of an OFDM system, such as 30 KHz.

The foregoing guard interval is a time interval between a moment transmission of a signal ends and a moment a latest echo signal of the signal is received. The parameter is directly proportional to a maximum sensing distance, which may be for example calculated through c/(2Rₘₐₓ), where Rₘₐₓ is the maximum sensing distance (which is sensing requirement information). For example, for a loop-back sensing signal, Rₘₐₓ represents a maximum distance between a sensing signal reception-transmission point and a signal transmission point. In some cases, a cyclic prefix (CP) of an OFDM signal may play a role of a minimum guard interval, and c is a speed of light.

The foregoing frequency domain start position refers to a start frequency point, or may be an index of a start Resource Element (RE) or a start Resource Block (RB).

The foregoing frequency domain resource length refers to a frequency domain bandwidth. The frequency domain bandwidth is inversely proportional to a distance resolution, a frequency domain bandwidth of each first signal is B≥c/(2ΔR), where c is the speed of light, and ΔR is the distance resolution.

The foregoing frequency domain resource interval is inversely proportional to a maximum unambiguous distance/latency. For the OFDM system, when continuous mapping is performed on the subcarrier, the frequency domain interval is equal to the subcarrier interval.

The foregoing time domain start position refers to a start time point, or may be a start symbol, slot, or frame index.

The foregoing time domain resource length is also referred to as a burst duration, and the time domain resource length is inversely proportional to a Doppler resolution (which is sensing requirement information).

The foregoing time domain resource interval is a time interval between two adjacent signals.

The foregoing signal power may be a value in a range of −20 dBm to 23 dBm at an interval of 2 dBm.

The foregoing sequence information includes generated sequence information (a ZC sequence or a PN sequence) to be adopted and a generation manner.

The foregoing signal direction includes angle information or beam information for sending a signal.

In some embodiments, the method in embodiments of this application further includes:

The first device sends first indication information to the third device. The first indication information is used for instructing the third device to process the first signal and/or perform information feedback.

The first indication information includes at least one of the following:
configuration identification information of the first signal;
a measurement quantity;
first threshold information, where the first threshold information is associated with performance indicator information of the first signal sent by the second device; and
a crystal oscillator frequency adjustment indication, where the crystal oscillator frequency adjustment indication is used for prohibiting the third device from performing crystal oscillator frequency adjustment, or used for instructing the third device to send adjusted crystal oscillator frequency information.

For example, in a case that the crystal oscillator frequency adjustment indication is used for prohibiting the third device from performing the crystal oscillator frequency adjustment, if the third device performs down-conversion on the first signal based on a first frequency and performs up-conversion on the second signal based on a second frequency, the first frequency is the same as the second frequency. In a case that the crystal oscillator frequency adjustment indication is used for instructing the third device to send the adjusted crystal oscillator frequency information, if the third device performs the crystal oscillator frequency adjustment, that is, the foregoing first frequency and second frequency are different, the third device feeds back the adjusted crystal oscillator frequency information to the first device or the second device, such as a difference between the first frequency and the second frequency.

In an implementation, the third device sends a difference Δf between the first frequency and the second frequency to the first device, and the first device eliminates impact of Δf when calculating target information, that is, the first device receives first information f_{D1,h}=f_{D,h}+(fₜ−fᵣ) and second information f′_{D2,h}=f_{D,h}+(f′ᵣ−fₜ). The first device obtains f_{D,h} based on the Δf, the first information, and the second information, where f_{D2,h}=f′_{D2,h}−Δf=f_{D,h}+(fᵣ−fₜ).

In another implementation, the third device sends the Δf to the second device, and the second device eliminates the Δf when calculating the second information, and then reports to the first device. In other words, the second device obtains f′_{D2,h}=f_{D,h}+(f′ᵣ−fₜ) through calculation, may obtain f_{D2,h}=f′_{D2,h}−Δf=f_{Dh}+(fᵣ−fₜ) based on the Δf, and then sends f_{D2,h} to the first device.

In some embodiments, the method in embodiments of this application further includes: obtaining, by the first device, first performance indicator information sent by the third device, where the first performance indicator information is performance indicator information of the first signal; adjusting signal configuration information of the first signal in a case that the first performance indicator information does not meet the first threshold information; or obtaining, by the first device, third indication information sent by the third device, where the third indication information is used for indicating that the performance indicator information of the first signal does not meet the first threshold information, and/or used for instructing the first device to adjust the first signal; and adjusting, by the first device, the signal configuration information of the first signal based on the third indication information, where the first information is a measurement result corresponding to the adjusted first signal.

In embodiments of this application, the third device measures the first signal, and may further obtain the foregoing first performance indicator information. The third device may feed back the foregoing first performance indicator information to the first device, so that the first device adjusts the configuration information of the first signal or determines that the measurement fails when determining that the first performance indicator information of the first signal does not meet the first threshold information, and feeds back a failure indication to a sensing requirement initiator, so as to re-perform the Doppler measurement. In some embodiments, the third device sends the foregoing third indication information to the first device after obtaining the first performance indicator information, so that the first device adjusts the signal configuration information of the first signal, thereby re-performing the Doppler measurement. For example, a transmission power or a time-frequency domain density of the first signal is increased, and the Doppler measurement is re-performed. In some embodiments, the first device determines, based on the third indication information, that the measurement fails, and feeds back a failure indication to the sensing requirement initiator.

In some embodiments, the foregoing first threshold information may be agreed in advance, or may be indicated by the first indication information.

In some embodiments, the method in embodiments of this application further includes:

The first device sends signal configuration information of the second signal to the second device and the third device.

In some embodiments, the method in embodiments of this application further includes:

The first device obtains signal configuration information of the second signal sent by the second device.

The first device sends the signal configuration information of the second signal to the third device.

In some embodiments, the method in embodiments of this application further includes:

The first device sends signal configuration recommendation information of the second signal to the second device.

The signal configuration information of the second signal is determined based on the signal configuration recommendation information.

In an implementation, the foregoing signal configuration recommendation information includes part or all of the signal configuration information of the second signal. The first device determines the signal configuration information of the second signal based on the signal configuration recommendation information, and sends the signal configuration information to the third device and the second device.

In some embodiments, the method in embodiments of this application further includes:

The first device sends second indication information to the second device. The second indication information is used for instructing the second device to process the second signal and/or perform information feedback.

The second indication information includes at least one of the following:
configuration identification information of the second signal;
a measurement quantity;
second threshold information, where the second threshold information is associated with performance indicator information of the second signal sent by the third device; and
a crystal oscillator frequency adjustment indication, where the crystal oscillator frequency adjustment indication is used for prohibiting the second device from performing crystal oscillator frequency adjustment, or used for instructing the second device to send adjusted crystal oscillator frequency information.

For example, in a case that the crystal oscillator frequency adjustment indication is used for prohibiting the second device from performing the crystal oscillator frequency adjustment, if the second device performs up-conversion on the first signal based on a third frequency and performs down-conversion on the second signal based on a fourth frequency, the third frequency is the same as the fourth frequency. In a case that the crystal oscillator frequency adjustment indication is used for instructing the second device to send the adjusted crystal oscillator frequency information, if the second device performs the crystal oscillator frequency adjustment, that is, the foregoing third frequency and fourth frequency are different, the second device feeds back the adjusted crystal oscillator frequency information to the first device or the third device, such as a difference between the third frequency and the fourth frequency.

In some embodiments, the method in embodiments of this application further includes: obtaining second performance indicator information sent by the second device, where the second performance indicator information is the performance indicator information of the second signal; adjusting signal configuration information of the second signal in a case that the second performance indicator information does not meet the second threshold information; or obtaining, by the first device, fourth indication information sent by the second device, where the fourth indication information is used for indicating that the second performance indicator information does not meet the second threshold information, and/or used for instructing the first device to adjust configuration information of the second signal; and adjusting, by the first device, the signal configuration information of the second signal based on the fourth indication information, where
the second information is a measurement result corresponding to the adjusted second signal.

In embodiments of this application, the second device measures the second signal, and may further obtain the foregoing second performance indicator information. The second device may feed back the foregoing second performance indicator information to the first device, so that the first device adjusts the configuration information of the second signal or determines that the measurement fails when determining that the second performance indicator information of the second signal does not meet the second threshold information, and feeds back a failure indication to a sensing requirement initiator, so as to re-perform the Doppler measurement. In some embodiments, the second device sends the foregoing fourth indication information to the first device after obtaining the second performance indicator information, so that the first device adjusts the signal configuration information of the second signal, so as to re-perform the Doppler measurement. For example, a transmission power or a time-frequency domain density of the second signal is increased, and the Doppler measurement is re-performed. In some embodiments, the first device determines, based on the fourth indication information, that the measurement fails, and feeds back a failure indication to the sensing requirement initiator.

In some embodiments, the configuration information of the second signal includes at least one of the following:
configuration identification information;
a waveform;
a subcarrier interval;
a guard interval;
a frequency domain start position;
a frequency domain resource length;
a frequency domain resource interval;
a time domain start position;
a time domain resource length;
a time domain resource interval;
a signal power;
sequence information;
a signal direction; and
relative time-domain position relationship information of the first signal and the second signal.

In some embodiments, the relative time-domain position relationship information includes at least one of the following:
a time interval T_{offset1} between a time domain start position of the first signal and a time domain start position of the second signal;
a time interval T_{offset2} between a time domain end position of the first signal and the time domain start position of the second signal;
a time interval T_{offset3} between the time domain end position of the first signal and a time domain end position of the second signal; and
a time interval T_{RTD} between the time domain start position of the first signal and the time domain end position of the second signal.

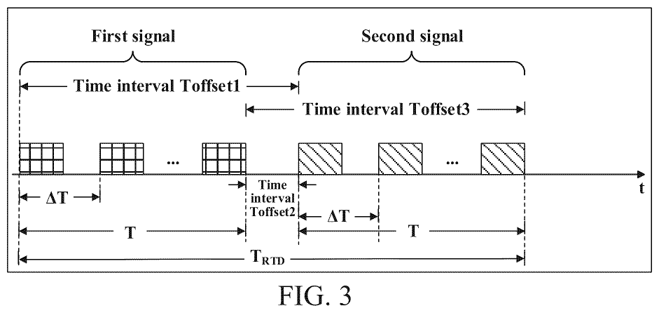

It should be noted that a time domain resource sent by the second signal is associated with a channel stability time. In other words, the time interval (T_{RTD}) between the time domain start position of the first signal and the time domain end position of the second signal is less than or equal to the channel stability time. The channel stability time is a time during which channel Doppler remains approximately constant. Specifically, a relationship between a time domain resource position of the second signal and a time domain resource position of the first signal is shown in FIG. 3.

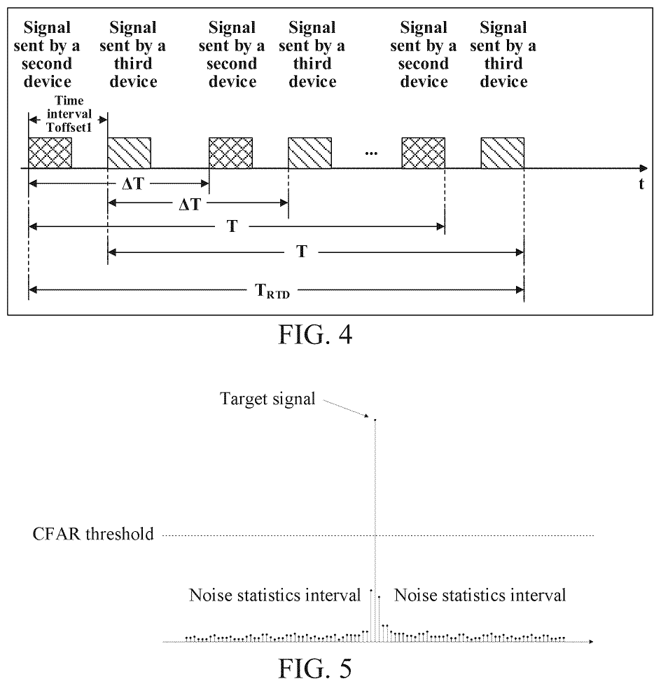

The first signal and the second signal may be sent successively, or may be sent alternately in a time domain. As shown in FIG. 4, in this case, a relative time domain position relationship between the first signal and the second signal does not include T_{offset2} and T_{offset3}.

In some embodiments, the configuration information of the first signal and/or the configuration information of the second signal and/or a related measurement feedback process may be agreed in advance. The second device and the third device may send the first signal and the second signal and feed back the first information and the second information based on the agreed content after detecting a Doppler measurement request.

In some embodiments, the performance indicator information includes at least one of the following:
signal strength information, for example, a Received Signal Strength Indication (RSSI) or a Reference Signal Received Power (RSRP);
signal to interference plus noise ratio (SINR) or signal to noise ratio (SNR) information; and SNR or SINR sensing information.

In some embodiments, the first signal or the second signal includes at least one of the following:
a reference signal, such as a Demodulation Reference Signal (DMRS), a downlink Channel-State-Information Reference Signal (CSI-RS), Positioning Reference Signal (PRS), or the like;
a communication data signal;
a synchronization signal, such as a Primary Synchronization Signal (PSS) or a Secondary Synchronization Signal (SSS);
a sensing signal, such as a Chirp signal; and
an integrated sensing and communication signal, that is, a signal that may be used for sensing and communication simultaneously.

In some embodiments, the method in embodiments of this application further includes: obtaining a sensing result based on the target information.

In embodiments of this application, after obtaining the target information, the first device may obtain a sensing result based on the target information. The sensing result is a sensing result corresponding to a sensing service with Doppler as a basic measurement quantity, including but not limited to: a motion speed, a motion direction, whether a target exists or a quantity of targets, a motion trajectory, an action, a gesture, and a vital sign (breathing, heartbeat, or the like).

The first device in embodiments of this application may be specifically a sensing network function device, or may be referred to as a sensing network element or a Sensing Management Function (SMF), which may be located on a Radio Access Network (RAN) side or a core network side, refers to a network node in the core network and/or the RAN that is responsible for at least one function such as sensing request processing, sensing resource scheduling, sensing information interaction, and sensing data processing, may be upgraded based on an AMF or a Location Management Function (LMF) in a 5G network, or may be another network node or a newly defined network node. Specifically, functional characteristics of a sensing network function/sensing network element may include at least one of the following:

(1) Interaction with a radio signal sending device and/or a radio signal measurement device (including a target terminal or a service base station of a target terminal or a base station associated with a target area) is performed for target information, where the target information includes a sensing processing request, a sensing capability, sensing auxiliary data, a sensing measurement quantity type, sensing resource configuration information, and the like, to obtain a target sensing result or a value of a sensing measurement quantity (an uplink measurement quantity or a downlink measurement quantity) sent by the radio signal measurement device, where the radio signal may also be referred to as a sensing signal.

(2) A sensing method to be used is determined based on factors such as a type of a sensing service, consumer information of the sensing service, required sensing Quality of Service (QOS) requirement information, a sensing capability of the radio signal sending device, and a sensing capability of the radio signal measurement device. The sensing method may include: sending by a base station A and receiving by a base station B, or sending by a base station and receiving by a terminal, or sending and receiving by a base station A, or sending by a terminal and receiving by a base station, or sending and receiving by a terminal, or sending by a terminal A and receiving by a terminal B, or the like.

(3) A sensing device serving the sensing service is determined based on the factors such as the type of the sensing service, consumer information of the sensing service, required sensing QoS requirement information, the sensing capability of the radio signal sending device, and the sensing capability of the radio signal measurement device, where the sensing device includes the radio signal sending device and/or the radio signal measurement device.

(4) Overall coordination and scheduling of resources required for the sensing service is managed, for example, sensing resources of a base station and/or a terminal are correspondingly configured.

(5) Data processing is performed on a value of the sensing measurement quantity, or calculation is performed to obtain a sensing result. Further, the sensing result is verified, a sensing precision is estimated, and the like.

In embodiments of this application, the sensing SNR may be a ratio of a sensing target association signal power to a noise power, and the sensing SNR may be a ratio of the sensing target association signal power to a sum of powers of noise and interference.

Radar detection is used as an example. A method for obtaining the sensing target association signal power may be at least one of the following options:

Constant False Alarm Rate (CFAR) detection is performed based on a one-dimensional latency graph obtained through fast-time dimension Fast Fourier Transform (FFT) of an echo signal, a sample point for which the CFAR exceeds a threshold and which has a maximum amplitude is used as a target sample point, and an amplitude thereof is used as a target signal amplitude to calculate the sensing target association signal power, as shown in FIG. 5.

The CFAR is performed based on a Doppler one-dimensional graph obtained through slow-time dimension FFT of the echo signal, the sample point for which the CFAR exceeds the threshold and which has the maximum amplitude is used as the target sample point, and the amplitude thereof is used as the target signal amplitude to calculate the sensing target association signal power, as shown in FIG. 5.

The CFAR is performed based on a two-dimensional latency-Doppler graph obtained through 2D-FFT of the echo signal, the sample point for which the CFAR exceeds the threshold and which has the maximum amplitude is used as the target sample point, and the amplitude thereof is used as the target signal amplitude to calculate the sensing target association signal power.

The CFAR is performed based on a three-dimensional latency-Doppler-angle graph obtained through 3D-FFT of the echo signal, the sample point for which the CFAR exceeds the threshold and which has the maximum amplitude is used as the target sample point, and the amplitude thereof is used as the target signal amplitude to calculate the sensing target association signal power.

In the method for determining the target signal amplitude, in addition to the manner of using, as the target sample point, the sample point for which the CFAR exceeds the threshold and which has the maximum amplitude, a mean value of the sample point for which the CFAR exceeds the threshold and which has the maximum amplitude and several nearest sample points of the sample point for which the CFAR exceeds the threshold is used as the target signal amplitude to calculate the sensing target association signal power.

The method for obtaining the SNR/SINR of the echo signal may be at least one of the following options:

The CFAR is performed on a one-dimensional latency graph obtained through fast-time dimension FFT of the echo signal, the sample point for which the CFAR exceeds the threshold and which has the maximum amplitude is used as the target sample point, the amplitude thereof is used as the target signal amplitude, all sample points in the one-dimensional graph that are spaced apart from a position of the target sample point by ±ε or more sample points are used as interference/noise sample points, a mean interference/amplitude thereof is calculated as an interference/noise signal amplitude, as shown in FIG. 5, and finally the SNR/SINR is calculated based on the target signal amplitude and the interference/noise signal amplitude.

The CFAR is performed on a Doppler one-dimensional graph obtained through slow-time dimension FFT of the echo signal, the sample point for which the CFAR exceeds a threshold and which has a maximum amplitude is used as the target sample point, the amplitude thereof is used as the target signal amplitude, all sample points in the one-dimensional graph that are spaced apart from the position of the target sample point by +n or more sample points are used as interference/noise sample points, a mean amplitude thereof is calculated as an interference/noise signal amplitude, and finally the SNR/SINR is calculated based on the target signal amplitude and the interference/noise signal amplitude.

The CFAR is performed on a two-dimensional latency-Doppler graph obtained through 2D-FFT of the echo signal, the sample point for which the CFAR exceeds a threshold and which has a maximum amplitude is used as the target sample point, the amplitude thereof is used as the target signal amplitude, all sample points in the two-dimensional graph that are spaced apart from the target sample point by ±ε (in a fast time dimension) and ±η (in a slow time dimension) or more sample points are used as interference/noise sample points, a mean amplitude thereof is calculated as an interference/noise signal amplitude, and finally the SNR/SINR is calculated based on the target signal amplitude and the interference/noise signal amplitude.

The CFAR is performed on a three-dimensional latency-Doppler-angle graph obtained through 3D-FFT of the echo signal, the sample point for which the CFAR exceeds a threshold and which has a maximum amplitude is used as the target sample point, the amplitude thereof is used as the target signal amplitude, all sample points in the three-dimensional graph that are spaced apart from the target sample point by ±ε (in a fast time dimension), ±η (in a slow time dimension), and ±δ (in an angle dimension) or more sample points are used as interference/noise sample points, a mean amplitude thereof is calculated as an interference/noise signal amplitude, and finally the SNR/SINR is calculated based on the target signal amplitude and the interference/noise signal amplitude.

In the method for determining the target signal amplitude, in addition to the manner of using, as the target sample point, the sample point for which the CFAR exceeds the threshold and which has the maximum amplitude, a mean value of the sample point for which the CFAR exceeds the threshold and which has the maximum amplitude and several nearest sample points of the sample point for which the CFAR exceeds the threshold is used as the target signal amplitude.

A method for determining the interference/noise sample points may further be further screening based on the above determined interference/noise sample points. The screening method is as follows: For the one-dimensional latency graph, several sample points near a sample point with a latency of 0 are removed, and the remaining interference/noise sample points are used as noise sample points. For the one-dimensional Doppler graph, several sample points near a sample point with Doppler of 0 are removed, and the remaining interference/noise sample points are used as interference/noise sample points. For the two-dimensional latency-Doppler graph, interference/noise sample points within a strip range composed of all Doppler ranges except several points near a sample point with a latency of 0 are removed, and the remaining noise sample points are used as interference/noise sample points. For the three-dimensional latency-Doppler-angle graph, several sample points near a sample point with a time dimension of 0 and interference/noise sample points within a slice-like range composed of all Doppler ranges and all angle ranges are removed, and the remaining interference/noise sample points are used as interference/noise sample points.

In embodiments of this application, the first device obtains the first information and the second information. The first device obtains target information based on the first information and the second information. The first information is Doppler frequency shift information obtained by a third device by measuring a first signal sent by a second device. The second information is Doppler frequency shift information obtained by the second device by measuring a second signal sent by the third device. The target information is used for indicating Doppler frequency shift information between the second device and the third device. The foregoing first information includes a clock frequency offset of a transceiver device, the second information also includes the clock frequency offset of the transceiver device, and the transceiver devices corresponding to the first information and the second information are opposite. Therefore, the receiver-transmitter clock frequency offset can be counteracted through a certain algorithm based on the foregoing first information and second information, to accurately obtain Doppler frequency shift information between the second device and the third device, thereby improving accuracy of Doppler measurement.

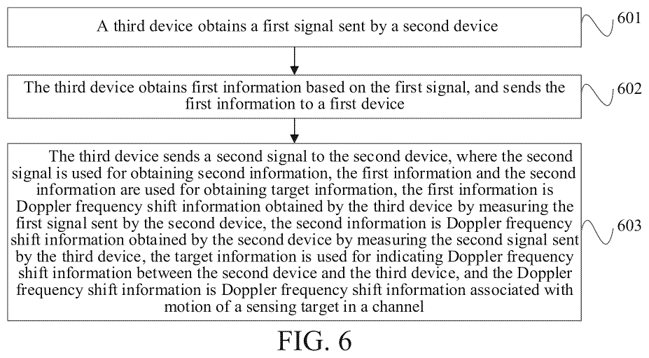

As shown in FIG. 6, an embodiment of this application further provides a Doppler measurement method, including the following steps.

Step 601: A third device obtains a first signal sent by a second device.

Step 602: The third device obtains first information based on the first signal, and sends the first information to a first device.

Step 603: The third device sends a second signal to the second device. The second signal is used for obtaining second information.

The first information and the second information are used for obtaining target information. The first information is Doppler frequency shift information obtained by the third device by measuring the first signal sent by the second device. The second information is Doppler frequency shift information obtained by the second device by measuring the second signal sent by the third device. The target information is used for indicating Doppler frequency shift information between the second device and the third device. The Doppler frequency shift information is Doppler frequency shift information associated with motion of a sensing target in a channel.

In embodiments of this application, the first device in this application may be a core network sensing network function device, the second device may be a network side device such as a base station, and the third device may be specifically a terminal.

In some embodiments, the first information is obtained by measuring the first signal by the third device. The second information is obtained by measuring the second signal by the second device.

In some embodiments, in embodiments of this application, the network side device sends the first signal through a downlink slot, and the terminal sends the second signal through an uplink slot.

In embodiments of this application, the third device obtains the first signal sent by the second device. The third device obtains first information based on the first signal, and sends the first information to the first device. The third device sends a second signal to the second device. The second signal is used for obtaining second information. The first information and the second information are used for obtaining target information. The target information is used for indicating Doppler frequency shift information between the second device and the third device. The foregoing first information includes a clock frequency offset of a transceiver device, the second information also includes the clock frequency offset of the transceiver device, and the transceiver devices corresponding to the first information and the second information are opposite. Therefore, the receiver-transmitter clock frequency offset can be counteracted through a certain algorithm based on the foregoing first information and second information, to accurately obtain Doppler frequency shift information between the first device and the second device, thereby improving accuracy of Doppler measurement.

In some embodiments, that the third device sends the second signal to the second device includes:

The third device obtains a second request sent by the first device, and the third device obtains the second request sent by the first device. The second request includes identification information of the second device and identification information of the third device, or includes the identification information of the second device.

The third device sends the second signal to the second device when determining to participate in the Doppler measurement.

In some embodiments, after the third device obtains the second request sent by the first device, the method further includes:

The third device sends a second response to the first device, where the second response is used for indicating that the third device participates in the Doppler measurement, or used for indicating that the third device refuses to participate in the Doppler measurement and/or a reason for refusing to participate in the Doppler measurement.

In some embodiments, the sending, by the third device, the second signal to the second device includes:
obtaining configuration information of the second signal; and
sending the second signal to the second device based on the configuration information of the second signal.

In some embodiments, the obtaining, by the third device, the first signal sent by the second device includes:
obtaining, by the third device, signal configuration information of the first signal; and
obtaining the first signal sent by the second device based on the signal configuration information of the first signal.

In some embodiments, the method in embodiments of this application further includes:

The third device obtains first indication information sent by the first device, where the first indication information is used for instructing the third device to process the first signal and/or perform information feedback.

The first indication information includes at least one of the following:
configuration identification information of the first signal;
a measurement quantity;
first threshold information, where the first threshold information is associated with performance indicator information of the first signal sent by the second device; and
a crystal oscillator frequency adjustment indication, where the crystal oscillator frequency adjustment indication is used for prohibiting the third device from performing crystal oscillator frequency adjustment, or used for instructing the third device to send adjusted crystal oscillator frequency information.

In some embodiments, the method in embodiments of this application further includes: sending first performance indicator information to the first device, where the first performance indicator information is the performance indicator information of the first signal; or sending fourth indication information and third indication information to the first device, where the third indication information is used for indicating that the first performance indicator information does not meet the first threshold information, and/or used for instructing the first device to adjust the first signal.

The first information is a measurement result corresponding to the adjusted first signal.

In some embodiments, before the third device obtains the first signal sent by the second device, the method in embodiments of this application further includes:

The third device sends device information of the third device to the first device, where the device information includes at least one of the following:
a frequency tolerance or frequency stability information;
position information;
mobility information;
battery status information;
temperature information;
available resource information;
fault status information;
a supported sensing measurement manner;
a supported sensing service;
a supported sensing measurement quantity;
a supported sensing waveform or communication waveform;
an operating band;
an operating bandwidth;
a transmission power; and
antenna configuration information.

In embodiments of this application, the third device obtains the first signal sent by the second device. The third device obtains first information based on the first signal, and sends the first information to the first device. The third device sends a second signal to the second device. The second signal is used for obtaining second information. The first information and the second information are used for obtaining target information. The target information is used for indicating Doppler frequency shift information between the second device and the third device. The foregoing first information includes a clock frequency offset of a transceiver device, the second information also includes the clock frequency offset of the transceiver device, and the transceiver devices corresponding to the first information and the second information are opposite. Therefore, the receiver-transmitter clock frequency offset can be counteracted through a certain algorithm based on the foregoing first information and second information, to accurately obtain Doppler frequency shift information between the first device and the second device, thereby improving accuracy of Doppler measurement.

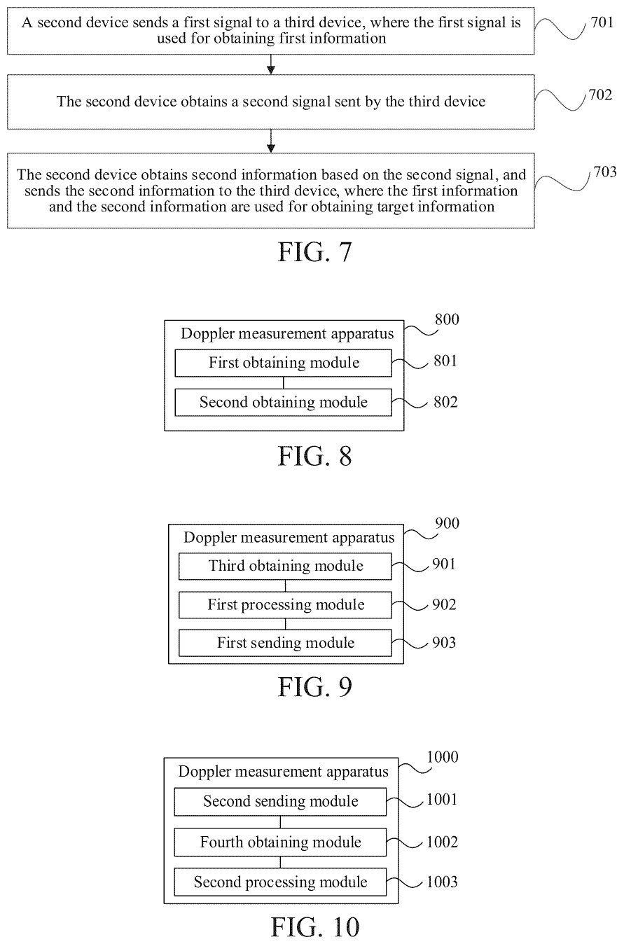

As shown in FIG. 7, an embodiment of this application further provides a Doppler measurement method, including the following steps.

Step 701: A second device sends a first signal to a third device. The first signal is used for obtaining first information.

Step 702: The second device obtains a second signal sent by the third device.

Step 703: The second device obtains second information based on the second signal, and sends the second information to a third device. The first information and the second information are used for obtaining target information.

The first information is Doppler frequency shift information obtained by a third device by measuring a first signal sent by a second device. The second information is Doppler frequency shift information obtained by the second device by measuring a second signal sent by the third device. The target information is used for indicating Doppler frequency shift information between the second device and the third device. The Doppler frequency shift information is Doppler frequency shift information associated with motion of a sensing target in a channel.

In embodiments of this application, the second device sends the first signal to the third device. The first signal is used for obtaining first information. The second device obtains the second signal sent by the third device. The second device obtains second information based on the second signal, and sends the second information to the third device. The first information and the second information are used for obtaining target information. The target information is used for indicating Doppler frequency shift information between the second device and the third device. The foregoing first information includes a clock frequency offset of a transceiver device, the second information also includes the clock frequency offset of the transceiver device, and the transceiver devices corresponding to the first information and the second information are opposite. Therefore, the receiver-transmitter clock frequency offset can be counteracted through a certain algorithm based on the foregoing first information and second information, to accurately obtain Doppler frequency shift information between the first device and the second device, thereby improving accuracy of Doppler measurement.

It should be noted that the Doppler measurement method performed by the second device or the third device corresponds to the Doppler measurement method performed by the first device. A specific interaction process has been described in detail in the method embodiment of a first device side, and the details are not described herein again.

The Doppler measurement method provided in embodiments of this application may be performed by a Doppler measurement apparatus. In embodiments of this application, the Doppler measurement apparatus provided in embodiments of this application is described by using an example in which the Doppler measurement apparatus performs the Doppler measurement method.

As shown in FIG. 8, an embodiment of this application provides a Doppler measurement apparatus 800, applied to a first device, and including:
a first obtaining module 801, configured to obtain first information and second information; and
a second obtaining module 802, configured to obtain target information based on the first information and the second information.

The first information is Doppler frequency shift information obtained by a third device by measuring a first signal sent by a second device. The second information is Doppler frequency shift information obtained by the second device by measuring a second signal sent by the third device. The target information is used for indicating Doppler frequency shift information between the second device and the third device. The Doppler frequency shift information is Doppler frequency shift information associated with motion of a sensing target in a channel.

In some embodiments, the first signal and the second signal have a same time domain resource format.

The time domain resource format includes a time domain resource length and a time domain resource interval.

In some embodiments, a time domain resource length of the first signal and a time domain resource length of the second signal are associated with a Doppler resolution; and/or a time domain resource interval of the first signal and a time domain resource interval of the second signal are associated with a maximum unambiguous Doppler frequency shift.

In some embodiments, the apparatus in this embodiment of this application further includes:
a third sending module, configured to send a first request to the second device, and send a second request to the third device before the first obtaining module obtains the first information and the second information, where the first request is used for requesting a second device to perform Doppler measurement, and the second request is used for requesting the third device to perform Doppler measurement; and
a fourth obtaining module, configured to obtain a first response sent by the second device and a second response sent by the third device.

The first response is used for indicating that the second device participates in the Doppler measurement, or used for indicating that the second device refuses to participate in the Doppler measurement and/or a reason for refusing to participate in the Doppler measurement. The second response is used for indicating that the third device participates in the Doppler measurement, or used for indicating that the third device refuses to participate in the Doppler measurement and/or a reason for refusing to participate in the Doppler measurement.

The first information is obtained in a case that the first response indicates that the third device participates in the Doppler measurement.

The second information is obtained in a case that the second response indicates that the second device participates in the Doppler measurement.

In some embodiments, the apparatus in this embodiment of this application further includes:
an obtaining module, configured to obtain device information sent by a candidate second device and device information sent by a candidate third device; and
a first determination module, configured to determine the second device and the third device based on the device information.

The device information includes at least one of the following:
a frequency tolerance or frequency stability information;
position information;
mobility information;
battery status information;
temperature information;
available resource information;
fault status information;
a supported sensing measurement manner;
a supported sensing service;
a supported sensing measurement quantity;
a supported sensing waveform or communication waveform;
an operating band;
an operating bandwidth;
a transmission power; and
antenna configuration information.

In some embodiments, the apparatus in this embodiment of this application further includes:
a fourth sending module, configured to send configuration information of the first signal to the second device and the third device.

The configuration information of the first signal includes at least one of the following: configuration identification information;
a waveform;
a subcarrier interval;
a guard interval;
a frequency domain start position;
a frequency domain resource length;
a frequency domain resource interval;
a time domain start position;
a time domain resource length;
a time domain resource interval;
a signal power;
sequence information; and
a signal direction.

In some embodiments, the apparatus in this embodiment of this application further includes:
a fifth sending module, configured to send first indication information to the third device. The first indication information is used for instructing the third device to process the first signal and/or perform information feedback.

The first indication information includes at least one of the following:
configuration identification information of the first signal;
a measurement quantity;
first threshold information, where the first threshold information is associated with performance indicator information of the first signal sent by the second device; and
a crystal oscillator frequency adjustment indication, where the crystal oscillator frequency adjustment indication is used for prohibiting the third device from performing crystal oscillator frequency adjustment, or used for instructing the third device to send adjusted crystal oscillator frequency information.

In some embodiments, the apparatus in this embodiment of this application further includes:
a fifth obtaining module, configured to obtain first performance indicator information sent by the third device, where the first performance indicator information is performance indicator information of the first signal; a first adjustment module, configured to adjust signal configuration information of the first signal in a case that the first performance indicator information does not meet the first threshold information; or
further includes: a sixth obtaining module, configured to obtain third indication information sent by the third device, where the third indication information is used for indicating that the first performance indicator information does not meet the first threshold information, and/or used for instructing the first device to adjust the first signal; and a second adjustment module, configured to adjust the signal configuration information of the first signal based on the third indication information.

The first information is a measurement result corresponding to the adjusted first signal.

In some embodiments, the apparatus in this embodiment of this application further includes:
a sixth sending module, configured to send signal configuration information of the second signal to the second device and the third device.

In some embodiments, the apparatus in this embodiment of this application further includes:
a seventh obtaining module, configured to obtain signal configuration information of the second signal sent by the second device; and
a seventh sending module, configured to send the signal configuration information of the second signal to the third device.

In some embodiments, the apparatus in this embodiment of this application further includes:
an eighth sending module, configured to send signal configuration recommendation information of the second signal to the second device.

The signal configuration information of the second signal is determined based on the signal configuration recommendation information.

In some embodiments, the apparatus in this embodiment of this application further includes:
a ninth sending module, configured to send second indication information to the second device, where the second indication information is used for instructing the second device to process the second signal and/or perform information feedback.

The second indication information includes at least one of the following:
configuration identification information of the second signal;
a measurement quantity;
second threshold information, where the second threshold information is associated with performance indicator information of the second signal sent by the third device; and
a crystal oscillator frequency adjustment indication, where the crystal oscillator frequency adjustment indication is used for prohibiting the second device from performing crystal oscillator frequency adjustment, or used for instructing the second device to send adjusted crystal oscillator frequency information.

In some embodiments, the apparatus in this embodiment of this application further includes:
an eighth obtaining module, configured to obtain second performance indicator information sent by the second device, where the second performance indicator information is the performance indicator information of the second signal; a third adjustment module, configured to adjust the signal configuration information of the second signal in a case that the second performance indicator information does not meet the second threshold information; or further includes: a ninth obtaining module, configured to obtain fourth indication information sent by the second device, where the fourth indication information is used for indicating that the second performance indicator information does not meet the second threshold information, and/or used for instructing the first device to adjust configuration information of the second signal; and a fourth adjustment module, configured to adjust the signal configuration information of the second signal based on the fourth indication information.

The second information is a measurement result corresponding to the adjusted second signal.

In some embodiments, the configuration information of the second signal includes at least one of the following:
configuration identification information;
a waveform;
a subcarrier interval;
a guard interval;
a frequency domain start position;
a frequency domain resource length;
a frequency domain resource interval;
a time domain start position;
a time domain resource length;
a time domain resource interval;
a signal power;
sequence information;
a signal direction; and
relative time-domain position relationship information of the first signal and the second signal.

In some embodiments, the relative time-domain position relationship information includes at least one of the following:
a time interval between a time domain start position of the first signal and a time domain start position of the second signal;
a time interval between a time domain end position of the first signal and the time domain start position of the second signal;
a time interval between the time domain end position of the first signal and a time domain end position of the second signal; and
a time interval between the time domain start position of the first signal and the time domain end position of the second signal.

In some embodiments, the performance indicator information includes at least one of the following:
signal strength information;
signal to interference plus noise ratio SINR or signal to noise ratio SNR information; and SNR or SINR sensing information.

In some embodiments, the first signal or the second signal includes at least one of the following:
a reference signal;
a communication data signal;
a synchronization signal;
a sensing signal; and
an integrated sensing and communication signal.

In some embodiments, the apparatus in this embodiment of this application further includes:
a tenth obtaining module, configured to obtain a sensing result based on the target information.

In embodiments of this application, the first device obtains the first information and the second information. The first device obtains target information based on the first information and the second information. The first information is Doppler frequency shift information obtained by a third device by measuring a first signal sent by a second device. The second information is Doppler frequency shift information obtained by the second device by measuring a second signal sent by the third device. The target information is used for indicating Doppler frequency shift information between the second device and the third device. The foregoing first information includes a clock frequency offset of a transceiver device, the second information also includes the clock frequency offset of the transceiver device, and the transceiver devices corresponding to the first information and the second information are opposite. Therefore, the receiver-transmitter clock frequency offset can be counteracted through a certain algorithm based on the foregoing first information and second information, to accurately obtain Doppler frequency shift information between the second device and the third device, thereby improving accuracy of Doppler measurement.

As shown in FIG. 9, an embodiment of this application further provides a Doppler measurement apparatus 900, applied to a third device, and including:
a third obtaining module 901, configured to obtain a first signal sent by a second device;
a first processing module 902, configured to obtain first information based on the first signal, and send the first information to a first device; and
a first sending module 903, configured to send a second signal to the second device, where the second signal is used for obtaining second information.

The first information and the second information are used for obtaining target information. The first information is Doppler frequency shift information obtained by the third device by measuring the first signal sent by the second device. The second information is Doppler frequency shift information obtained by the second device by measuring the second signal sent by the third device. The target information is used for indicating Doppler frequency shift information between the second device and the third device. The Doppler frequency shift information is Doppler frequency shift information associated with motion of a sensing target in a channel.

In some embodiments, the first sending module includes:
a first obtaining submodule, configured to obtain a second request sent by the first device, where the second request is used for requesting the third device to perform Doppler measurement; and
a first sending submodule, configured to send the second signal to the second device when determining to participate in the Doppler measurement.

In some embodiments, in the apparatus in embodiments of this application, the first sending module further includes:
a second sending submodule, configured to send a second response to the first device after the first obtaining submodule obtains the second request sent by the first device, where the second response is used for indicating that the third device participates in the Doppler measurement, or used for indicating that the third device refuses to participate in the Doppler measurement and/or a reason for refusing to participate in the Doppler measurement.

In some embodiments, the first sending module includes:
a second obtaining submodule, configured to obtain configuration information of the second signal; and
a third sending submodule, configured to send the second signal to the second device based on the configuration information of the second signal.

In some embodiments, the third obtaining module includes:
a third obtaining submodule, configured to obtain signal configuration information of the first signal; and
a fourth obtaining submodule, configured to obtain the first signal sent by the second device based on the signal configuration information of the first signal.

In some embodiments, the apparatus in this embodiment of this application further includes:
an eleventh obtaining module, configured to obtain first indication information sent by the first device, where the first indication information is used for instructing the third device to process the first signal and/or perform information feedback.

The first indication information includes at least one of the following:
configuration identification information of the first signal;
a measurement quantity;
first threshold information, where the first threshold information is associated with performance indicator information of the first signal sent by the second device; and
a crystal oscillator frequency adjustment indication, where the crystal oscillator frequency adjustment indication is used for prohibiting the third device from performing crystal oscillator frequency adjustment, or used for instructing the third device to send adjusted crystal oscillator frequency information.

In some embodiments, the apparatus in this embodiment of this application further includes:
a tenth sending module, configured to send first performance indicator information to the first device, where the first performance indicator information is the performance indicator information of the first signal; or
send fourth indication information and third indication information to the first device, where the third indication information is used for indicating that the first performance indicator information does not meet the first threshold information, and/or used for instructing the first device to adjust the first signal.

The first information is a measurement result corresponding to the adjusted first signal.

In some embodiments, the apparatus in this embodiment of this application further includes:
an eleventh sending module, configured to send device information to the first device, where the device information includes at least one of the following:
a frequency tolerance or frequency stability information;
position information;
mobility information;
battery status information;
temperature information;
available resource information;
fault status information;
a supported sensing measurement manner;
a supported sensing service;
a supported sensing measurement quantity;
a supported sensing waveform or communication waveform;
an operating band;
an operating bandwidth;
a transmission power; and
antenna configuration information.

In embodiments of this application, the third device obtains the first signal sent by the second device. The third device obtains first information based on the first signal, and sends the first information to the first device. The third device sends a second signal to the second device. The second signal is used for obtaining second information. The first information and the second information are used for obtaining target information. The target information is used for indicating Doppler frequency shift information between the second device and the third device. The foregoing first information includes a clock frequency offset of a transceiver device, the second information also includes the clock frequency offset of the transceiver device, and the transceiver devices corresponding to the first information and the second information are opposite. Therefore, the receiver-transmitter clock frequency offset can be counteracted through a certain algorithm based on the foregoing first information and second information, to accurately obtain Doppler frequency shift information between the first device and the second device, thereby improving accuracy of Doppler measurement.

As shown in FIG. 10, an embodiment of this application further provides a Doppler measurement apparatus 1000, applied to a second device, and including:
a second sending module 1001, configured to send a first signal to a third device, where the first signal is used for obtaining first information;
a fourth obtaining module 1002, configured to obtain a second signal sent by the third device; and
a second processing module 1003, configured to obtain second information based on the second signal, and send the second information to the third device, where the first information and the second information are used for obtaining target information.

The first information is Doppler frequency shift information obtained by a third device by measuring a first signal sent by a second device. The second information is Doppler frequency shift information obtained by the second device by measuring a second signal sent by the third device. The target information is used for indicating Doppler frequency shift information between the second device and the third device. The Doppler frequency shift information is Doppler frequency shift information associated with motion of a sensing target in a channel.

In embodiments of this application, the second device sends the first signal to the third device. The first signal is used for obtaining first information. The second device obtains the second signal sent by the third device. The second device obtains second information based on the second signal, and sends the second information to the third device. The first information and the second information are used for obtaining target information. The target information is used for indicating Doppler frequency shift information between the second device and the third device. The foregoing first information includes a clock frequency offset of a transceiver device, the second information also includes the clock frequency offset of the transceiver device, and the transceiver devices corresponding to the first information and the second information are opposite. Therefore, the receiver-transmitter clock frequency offset can be counteracted through a certain algorithm based on the foregoing first information and second information, to accurately obtain Doppler frequency shift information between the first device and the second device, thereby improving accuracy of Doppler measurement.

The Doppler measurement apparatus in embodiments of this application may be an electronic device, for example, an electronic device having an operating system, or may be a component in the electronic device, for example, an integrated circuit or a chip. The electronic device may be a terminal, or may be another device other than the terminal. For example, the terminal may include but is not limited to the foregoing listed types of the terminal 11, and the another device may be a server, a Network Attached Storage (NAS), or the like. This is not specifically limited in embodiments of this application.

The Doppler measurement apparatus provided in embodiments of this application can implement all processes implemented in the method embodiments of FIG. 2 to FIG. 7, and achieve the same technical effect. To avoid repetition, details are not described herein again.

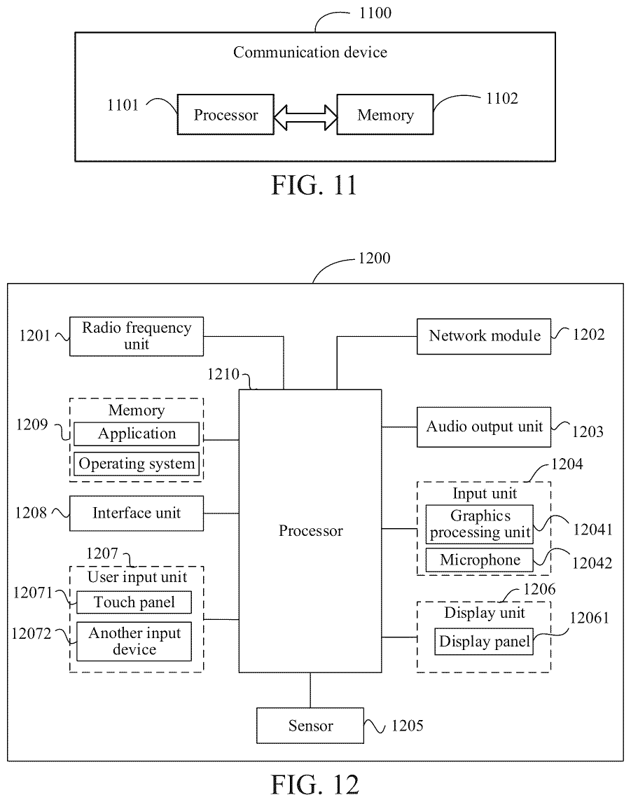

In some embodiments, as shown in FIG. 11, an embodiment of this application further provides a communication device 1100, including a processor 1101 and a memory 1102. The memory 1102 stores a program or an instruction executable in the processor 1101. For example, when the communication device 1100 is a first device, the program or the instruction, when executed by the processor 1101, implements the steps of embodiments of the foregoing Doppler measurement method performed by the first device, and can achieve the same technical effect. When the communication device 1100 is a second device, the program or the instruction, when executed by the processor 1101, implements the steps of embodiments of the foregoing Doppler measurement method performed by the second device, and can achieve the same technical effect. When the communication device 1100 is a third device, the program or the instruction, when executed by the processor 1101, implements all steps of embodiments of the foregoing Doppler measurement method performed by the third device, and can achieve the same technical effect. To avoid repetition, details are not described herein again.

An embodiment of this application further provides a third device, including a processor and a communication interface. The communication interface is configured to obtain a first signal sent by a second device. The processor is configured to obtain first information based on the first signal. The communication interface sends the first information to a first device, and send a second signal to the second device, where the second signal is used for obtaining second information. The first information and the second information are used for obtaining target information. The first information is Doppler frequency shift information obtained by the third device by measuring the first signal sent by the second device. The second information is Doppler frequency shift information obtained by the second device by measuring the second signal sent by the third device. The target information is used for indicating Doppler frequency shift information between the second device and the third device. The Doppler frequency shift information is Doppler frequency shift information associated with motion of a sensing target in a channel. The implementation processes and implementations of the above method embodiments are applicable to this embodiment, and can achieve the same technical effect. Specifically, FIG. 12 is a schematic diagram of a hardware structure of a third device (which is specifically a terminal) for implementing an embodiment of this application.

The terminal 1200 includes but is not limited to: at least some of components such as a radio frequency unit 1201, a network module 1202, an audio output unit 1203, an input unit 1204, a sensor 1205, a display unit 1206, a user input unit 1207, an interface unit 1208, a memory 1209, and a processor 1210.

A person skilled in the art may understand that the terminal 1200 may further include a power supply (such as a battery) that supplies power to components. The power supply may be logically connected to the processor 1210 through a power management system, thereby implementing functions such as management of charging, discharging, and power consumption through the power management system. The terminal structure shown in FIG. 12 constitutes no limitation on the terminal, and the terminal may include more or fewer components than those shown in the figure, or some merged components, or different component arrangements. Details are not described herein again.

It should be noted that, in this embodiment of this application, the input unit 1204 may include a Graphics Processing Unit (GPU) 12041 and a microphone 12042. The graphics processing unit 12041 processes image data of a static picture or a video obtained by an image capturing apparatus (for example, a camera) in a video capturing mode or an image capturing mode. The display unit 1206 may include a display panel 12061. The display panel 12061 may be configured in a form such as a liquid crystal display or an organic light-emitting diode. The user input unit 1207 includes at least one of a touch panel 12071 and another input device 12072. The touch panel 12071 is also referred to as a touch screen. The touch panel 12071 may include two parts: a touch detection apparatus and a touch controller. The another input device 12072 may include but is not limited to a physical keyboard, a function button (such as a volume control button or a power button), a trackball, a mouse, and a joystick. Details are not described herein again.

In this embodiment of this application, the radio frequency unit 1201 receives downlink data from a network side device, and then may transmit the data to the processor 1210 for processing. In addition, the radio frequency unit 1201 may send uplink data to the network side device. Generally, the radio frequency unit 1201 includes but is not limited to an antenna, an amplifier, a transceiver, a coupler, a low noise amplifier, a duplexer, and the like.

The memory 1209 may be configured to store a software program or instructions and various data. The memory 1209 may include mainly a first storage area for storing a program or instructions and a second storage area for storing data. The first storage area may store an operating system, an application or an instruction required for at least one function (such as a sound playback function and an image playback function), and the like. In addition, the memory 1209 may include a volatile memory or a non-volatile memory, or the memory 1209 may include both the volatile memory and the non-volatile memory. The non-volatile memory may be a Read-Only Memory (ROM), a Programmable ROM (PROM), an Erasable PROM (EPROM), an Electrically EPROM (EEPROM), or a flash memory. The volatile memory may be a Random Access Memory (RAM), a Static RAM (SRAM), a Dynamic RAM (DRAM), a Synchronous DRAM (SDRAM), a Double Data Rate SDRAM (DDR SDRAM), an Enhanced SDRAM (ESDRAM), a Synch Link DRAM (SLDRAM), and a Direct Rambus RAM (DRRAM). The memory 1209 in this embodiment of this application includes but is not limited to the above and any other suitable types of memories.

The processor 1210 may include one or more processing units. In some embodiments, an application processor and a modem processor are integrated into the processor 1210. The application processor is mainly configured to process operations related to an operating system, a user interface, an application, and the like. The modem processor such as a baseband processor is mainly configured to process a wireless communication signal. It may be understood that the foregoing modem processor may alternatively not be integrated into the processor 1210.

The radio frequency unit 1201 is configured to obtain a first signal sent by a second device. The processor 1210 is configured to obtain first information based on the first signal, and send the first information to a first device through the radio frequency unit 1201. The radio frequency unit 1201 is configured to send a second signal to the second device, where the second signal is used for obtaining second information.

The first information and the second information are used for obtaining target information. The first information is Doppler frequency shift information obtained by the third device by measuring the first signal sent by the second device. The second information is Doppler frequency shift information obtained by the second device by measuring the second signal sent by the third device. The target information is used for indicating Doppler frequency shift information between the second device and the third device. The Doppler frequency shift information is Doppler frequency shift information associated with motion of a sensing target in a channel.

In some embodiments, the radio frequency unit 1201 is further configured to:
obtain a second request sent by the first device, where the second request is used for requesting the third device to perform Doppler measurement; and
send the second signal to the second device when determining to participate in the Doppler measurement.

In some embodiments, the radio frequency unit 1201 is further configured to: send a second response to the first device, where the second response is used for indicating that the third device participates in the Doppler measurement, or used for indicating that the third device refuses to participate in the Doppler measurement and/or a reason for refusing to participate in the Doppler measurement.

In some embodiments, the radio frequency unit 1201 is further configured to: obtain configuration information of the second signal; and send the second signal to the second device based on the configuration information of the second signal.

In some embodiments, the radio frequency unit 1201 is further configured to:
obtain signal configuration information of the first signal; and
obtain the first signal sent by the second device based on the signal configuration information of the first signal.

In some embodiments, the radio frequency unit 1201 is further configured to: obtain first indication information sent by the first device, where the first indication information is used for instructing the third device to process the first signal and/or perform information feedback.

The first indication information includes at least one of the following:
configuration identification information of the first signal;
a measurement quantity;
first threshold information, where the first threshold information is associated with performance indicator information of the first signal sent by the second device; and
a crystal oscillator frequency adjustment indication, where the crystal oscillator frequency adjustment indication is used for prohibiting the third device from performing crystal oscillator frequency adjustment, or used for instructing the third device to send adjusted crystal oscillator frequency information.

In some embodiments, the radio frequency unit 1201 is further configured to:
send first performance indicator information to the first device, where the first performance indicator information is the performance indicator information of the first signal; or
send fourth indication information and third indication information to the first device, where the third indication information is used for indicating that the first performance indicator information does not meet the first threshold information, and/or used for instructing the first device to adjust the first signal.

The first information is a measurement result corresponding to the adjusted first signal.

In some embodiments, the radio frequency unit 1201 is further configured to: send device information of the third device to the first device, where the device information includes at least one of the following:
a frequency tolerance or frequency stability information;
position information;
mobility information;
battery status information;
temperature information;
available resource information;
fault status information;
a supported sensing measurement manner;
a supported sensing service;
a supported sensing measurement quantity;
a supported sensing waveform or communication waveform;
an operating band;
an operating bandwidth;
a transmission power; and
antenna configuration information.

In embodiments of this application, the third device obtains the first signal sent by the second device. The third device obtains first information based on the first signal, and sends the first information to the first device. The third device sends a second signal to the second device. The second signal is used for obtaining second information. The first information and the second information are used for obtaining target information. The target information is used for indicating Doppler frequency shift information between the second device and the third device. The foregoing first information includes a clock frequency offset of a transceiver device, the second information also includes the clock frequency offset of the transceiver device, and the transceiver devices corresponding to the first information and the second information are opposite. Therefore, the receiver-transmitter clock frequency offset can be counteracted through a certain algorithm based on the foregoing first information and second information, to accurately obtain Doppler frequency shift information between the first device and the second device, thereby improving accuracy of Doppler measurement.

An embodiment of this application further provides a network side device (a first device), including a processor and a communication interface. The communication interface is configured to obtain first information and second information. The processor is configured to obtain target information based on the first information and the second information. The first information is Doppler frequency shift information obtained by a third device by measuring a first signal sent by a second device. The second information is Doppler frequency shift information obtained by the second device by measuring a second signal sent by the third device. The target information is used for indicating Doppler frequency shift information between the second device and the third device. The Doppler frequency shift information is Doppler frequency shift information associated with motion of a sensing target in a channel. The network side device embodiment corresponds to the foregoing method embodiment of the first device. The implementation processes and implementations of the foregoing method embodiment are all applicable to the embodiment of the network side device, and can achieve the same technical effect.

An embodiment of this application further provides a network side device (a second device), including a processor and a communication interface. The communication interface is configured to send a first signal to a third device, where the first signal is used for obtaining first information; and obtain the second signal sent by the third device. The processor is configured to obtain second information based on the second signal, and sends the second information to the third device through the communication interface. The first information and the second information are used for obtaining target information. The first information is Doppler frequency shift information obtained by a third device by measuring a first signal sent by a second device. The second information is Doppler frequency shift information obtained by the second device by measuring a second signal sent by the third device. The target information is used for indicating Doppler frequency shift information between the second device and the third device. The Doppler frequency shift information is Doppler frequency shift information associated with motion of a sensing target in a channel. The network side device embodiment corresponds to the foregoing method embodiment of the second device. The implementation processes and implementations of the foregoing method embodiment are all applicable to the embodiment of the network side device, and can achieve the same technical effect.

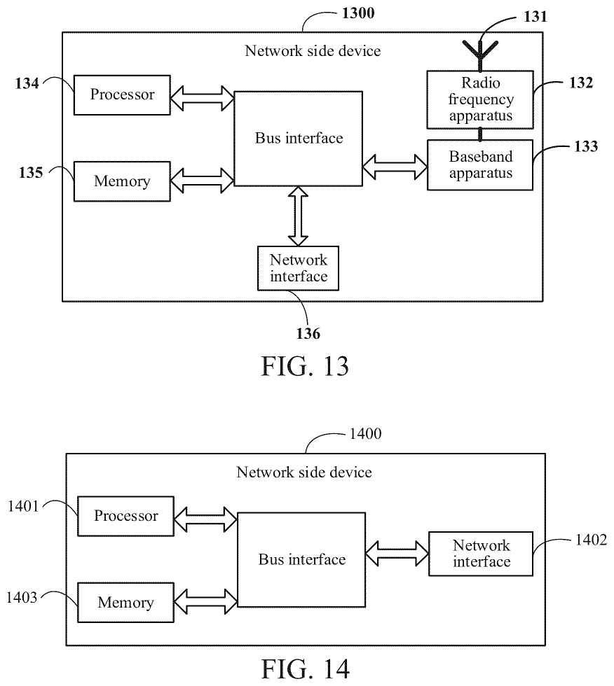

Specifically, an embodiment of this application further provides a network side device. As shown in FIG. 13, a network side device 1300 includes an antenna 131, a radio frequency apparatus 132, a baseband apparatus 133, a processor 134, and a memory 135. The antenna 131 is connected to the radio frequency apparatus 132. In an uplink direction, the radio frequency apparatus 132 receives information through the antenna 131, and sends the received information to the baseband apparatus 133 for processing. In a downlink direction, the baseband apparatus 133 processes to-be-sent information, and sends the processed to-be-sent information to the radio frequency apparatus 132. The radio frequency apparatus 132 processes the received information, and then sends the processed information through the antenna 131.

In the above embodiment, the method performed by the second device may be implemented in the baseband apparatus 133. The baseband apparatus 133 includes a baseband processor.

The baseband apparatus 133 may include, for example, at least one baseband board. A plurality of chips are arranged on the baseband board, as shown in FIG. 13. One of the chips is, for example, a baseband processor, and is connected to the memory 135 through a bus interface to call a program in the memory 135, to perform the operations of the network device shown in the foregoing method embodiment.

The network side device may further include a network interface 136. The interface is, for example, a common public radio interface (CPRI).

Specifically, the network side device 1300 in this embodiment of this application further includes instructions or a program stored in the memory 135 and executable in the processor 134. The processor 134 calls the instructions or the program in the memory 135 to perform the method performed by each module shown in FIG. 10, and achieves the same technical effect. To avoid repetition, details are not described herein.

Specifically, an embodiment of this application further provides a network side device. As shown in FIG. 14, a network side device 1400 includes a processor 1401, a network interface 1402, and a memory 1403. The network interface 1402 is, for example, a common public radio interface (CPRI).

Specifically, the network side device 1400 in this embodiment of this application further includes instructions or a program stored in the memory 1403 and executable in the processor 1401. The processor 1401 calls the instructions or the program in the memory 1403 to perform the method performed by each module shown in FIG. 8, and achieves the same technical effect. To avoid repetition, details are not described herein.

An embodiment of this application further provides a readable storage medium. The readable storage medium stores a program or an instruction. The program or the instruction, when executed by a processor, implements the processes of embodiments of the above Doppler measurement method, and can achieve the same technical effect. To avoid repetition, details are not described herein again.

The processor is a processor in the terminal described in the foregoing embodiments. The readable storage medium includes a computer-readable storage medium, such as a computer read-only memory ROM, a random access memory RAM, a magnetic disk, or an optical disk.

An embodiment of this application further provides a chip. The chip includes a processor and a communication interface. The communication interface is coupled to the processor. The processor is configured to execute a program or an instruction, to implement the processes of embodiments of the foregoing Doppler measurement method, and can achieve the same technical effect. To avoid repetition, details are not described herein again.

It should be understood that the chip mentioned in this embodiment of this application may also be referred to as a system level chip, a system chip, a chip system, a system on chip, or the like.

An embodiment of this application further provides a computer program/program product. The computer program/program product is stored in a storage medium. The computer program/program product is executed by at least one processor to implement the processes of embodiments of the foregoing Doppler measurement method, and can achieve the same technical effect. To avoid repetition, details are not described herein again.

An embodiment of this application further provides a Doppler measurement system, including a first device, a second device, and a third device. The first device may be configured to perform the steps of the method performed by the first device as described above, the second device may be configured to perform the steps of the method performed by the second device as described above, and the third device may be configured to perform the steps of the method performed by the third device as described above.

It should be noted that the term “comprise,” “include” or any other variant herein are intended to encompass non-exclusive inclusion, so that a process, a method, an article, or an apparatus including a series of elements not only includes those elements, but also includes another element not listed explicitly, or includes intrinsic elements for the process, the method, the article, or the apparatus. Without any further limitation, an element defined by the phrase “include one . . . ” does not exclude existence of an additional same element in the process, the method, the article, or the apparatus that includes the element. In addition, it should be noted that the scope of the method and the apparatus in embodiments of this application is not limited to function execution in the order shown or discussed, and may further include function execution in a substantially simultaneous manner or in the opposite order based on the functions. For example, the described method may be performed in different order from the described order, and various steps may also be added, omitted, or combined. In addition, features described with reference to some examples may be combined in another example.

Through the descriptions of the foregoing implementations, a person skilled in the art may clearly learn that the method in the foregoing embodiments may be implemented by software with a necessary universal hardware platform, or may be implemented by hardware. However, in many cases, the software with a necessary universal hardware platform is a preferred implementation. Based on such an understanding, the technical solutions of this application, in essence, or a part contributing to the related art may be embodied in a form of a computer software product. The computer software product is stored in a storage medium (such as a ROM/RAM, a magnetic disk, or an optical disk), including a plurality of instructions for causing a terminal (which may be a mobile phone, a computer, a server, an air conditioner, a network device, or the like) to perform the method in embodiments of this application.

Although embodiments of this application are described above with reference to the accompanying drawings, this application is not limited to the specific implementations described above. The foregoing specific implementations are illustrative but not restrictive. With the enlightenment of this application, a person of ordinary skill in the art may make many forms without departing from the concept of this application and the protection scope of the claims. These forms fall within the protection of this application.

What is claimed is:

1. A Doppler measurement method, performed by a first device, comprising:
obtaining first information and second information; and
obtaining target information based on the first information and the second information, wherein:
the first information is Doppler frequency shift information obtained by a third device by measuring a first signal sent by a second device,
the second information is Doppler frequency shift information obtained by the second device by measuring a second signal sent by the third device,
the target information is configured to indicate Doppler frequency shift information between the second device and the third device, and
the Doppler frequency shift information is Doppler frequency shift information associated with motion of a sensing target in a channel.

2. The method according to claim 1, wherein the first signal and the second signal have a same time domain resource format; and
the time domain resource format comprises a time domain resource length and a time domain resource interval.

3. The method according to claim 1, wherein a time domain resource length of the first signal and a time domain resource length of the second signal are associated with a Doppler resolution; or
a time domain resource interval of the first signal and a time domain resource interval of the second signal are associated with a maximum unambiguous Doppler frequency shift.

4. The method according to claim 1, wherein before the obtaining first information and second information, the method further comprises:
sending a first request to the second device, and sending a second request to the third device, wherein the first request is configured to request a second device to perform Doppler measurement, and the second request is configured to request the third device to perform Doppler measurement; and
obtaining a first response sent by the second device and a second response sent by the third device, wherein:
the first response is configured to indicate that the second device participates in the Doppler measurement, or configured to indicate that the second device refuses to participate in the Doppler measurement or a reason for refusing to participate in the Doppler measurement;
the second response is configured to indicate that the third device participates in the Doppler measurement, or configured to indicate that the third device refuses to participate in the Doppler measurement or a reason for refusing to participate in the Doppler measurement;
the first information is obtained when the first response indicates that the third device participates in the Doppler measurement; and
the second information is obtained when the second response indicates that the second device participates in the Doppler measurement.

5. The method according to claim 4, further comprising:
obtaining device information sent by a candidate second device and device information sent by a candidate third device; and
determining the second device and the third device based on the device information, wherein
the device information comprises at least one of the following:
a frequency tolerance or frequency stability information;
position information;
mobility information;
battery status information;
temperature information;
available resource information;
fault status information;
a supported sensing measurement manner;
a supported sensing service;
a supported sensing measurement quantity;
a supported sensing waveform or communication waveform;
an operating band;
an operating bandwidth;
a transmission power; or
antenna configuration information.

6. The method according to claim 1, further comprising:
sending configuration information of the first signal to the second device and the third device, wherein
the configuration information of the first signal comprises at least one of the following:
configuration identification information;
a waveform;
a subcarrier interval;
a guard interval;
a frequency domain start position;
a frequency domain resource length;
a frequency domain resource interval;
a time domain start position;
a time domain resource length;
a time domain resource interval;
a signal power;
sequence information; or
a signal direction.

7. The method according to claim 1, further comprising:
sending first indication information to the third device, wherein the first indication information is configured to instruct the third device to process the first signal or perform information feedback; and
the first indication information comprises at least one of the following:
configuration identification information of the first signal;
a measurement quantity;
first threshold information, wherein the first threshold information is associated with performance indicator information of the first signal sent by the second device; or
a crystal oscillator frequency adjustment indication, wherein the crystal oscillator frequency adjustment indication is configured to prohibit the third device from performing crystal oscillator frequency adjustment, or configured to instruct the third device to send adjusted crystal oscillator frequency information.

8. The method according to claim 7, further comprising:
obtaining first performance indicator information sent by the third device, wherein the first performance indicator information is performance indicator information of the first signal; and
adjusting signal configuration information of the first signal when the first performance indicator information does not meet the first threshold information; or
obtaining third indication information sent by the third device, wherein the third indication information is configured to indicate that the first performance indicator information does not meet the first threshold information, or configured to instruct the first device to adjust the first signal; and
adjusting the signal configuration information of the first signal based on the third indication information, wherein
the first information is a measurement result corresponding to the adjusted first signal.

9. The method according to claim 1, further comprising:
sending signal configuration information of the second signal to the second device and the third device.

10. The method according to claim 1, further comprising:
obtaining signal configuration information of the second signal sent by the second device; and
sending the signal configuration information of the second signal to the third device.

11. The method according to claim 9, further comprising:
sending signal configuration recommendation information of the second signal to the second device, wherein
the signal configuration information of the second signal is determined based on the signal configuration recommendation information.

12. The method according to claim 9, further comprising:
sending second indication information to the second device, wherein the second indication information is configured to instruct the second device to process the second signal or perform information feedback, wherein
the second indication information comprises at least one of the following:
configuration identification information of the second signal;
a measurement quantity;
second threshold information, wherein the second threshold information is associated with performance indicator information of the second signal sent by the third device; or
a crystal oscillator frequency adjustment indication, wherein the crystal oscillator frequency adjustment indication is configured to prohibit the second device from performing crystal oscillator frequency adjustment, or configured to instruct the second device to send adjusted crystal oscillator frequency information.

13. The method according to claim 12, further comprising:
obtaining second performance indicator information sent by the second device, wherein the second performance indicator information is the performance indicator information of the second signal; and
adjusting signal configuration information of the second signal when the second performance indicator information does not meet the second threshold information; or
obtaining fourth indication information sent by the second device, wherein the fourth indication information is configured to indicate that the second performance indicator information does not meet the second threshold information, or configured to instruct the first device to adjust configuration information of the second signal; and
adjusting the signal configuration information of the second signal based on the fourth indication information, wherein
the second information is a measurement result corresponding to the adjusted second signal.

14. The method according to claim 9, wherein the configuration information of the second signal comprises at least one of the following:
configuration identification information;
a waveform;
a subcarrier interval;
a guard interval;
a frequency domain start position;
a frequency domain resource length;
a frequency domain resource interval;
a time domain start position;
a time domain resource length;
a time domain resource interval;
a signal power;
sequence information;
a signal direction; or
relative time-domain position relationship information of the first signal and the second signal.

15. The method according to claim 14, wherein the relative time-domain position relationship information comprises at least one of the following:
a time interval between a time domain start position of the first signal and a time domain start position of the second signal;
a time interval between a time domain end position of the first signal and the time domain start position of the second signal;
a time interval between the time domain end position of the first signal and a time domain end position of the second signal; or
a time interval between the time domain start position of the first signal and the time domain end position of the second signal.

16. The method according to claim 7, wherein the performance indicator information comprises at least one of the following:
signal strength information;
Signal to Interference plus Noise Ratio (SINR) or Signal to Noise Ratio (SNR) information; or
SNR or SINR sensing information.

17. The method according to claim 1, wherein the first signal or the second signal comprises at least one of the following:
a reference signal;
a communication data signal;
a synchronization signal;
a sensing signal; or
an integrated sensing and communication signal.

18. The method according to claim 1, further comprising:
obtaining a sensing result based on the target information.

19. A first device, comprising:
a memory storing computer-readable instructions; and
a processor coupled to the memory and configured to execute the computer-readable instructions, wherein the computer-readable instructions, when executed by the processor, cause the processor to perform operations comprising:
obtaining first information and second information; and
obtaining target information based on the first information and the second information, wherein:
the first information is Doppler frequency shift information obtained by a third device by measuring a first signal sent by a second device,
the second information is Doppler frequency shift information obtained by the second device by measuring a second signal sent by the third device,
the target information is configured to indicate Doppler frequency shift information between the second device and the third device, and
the Doppler frequency shift information is Doppler frequency shift information associated with motion of a sensing target in a channel.

20. A non-transitory computer-readable medium storing instructions that, when executed by a processor of a first device, cause the processor to perform operations comprising:
obtaining first information and second information; and
obtaining target information based on the first information and the second information, wherein:
the first information is Doppler frequency shift information obtained by a third device by measuring a first signal sent by a second device,
the second information is Doppler frequency shift information obtained by the second device by measuring a second signal sent by the third device,
the target information is configured to indicate Doppler frequency shift information between the second device and the third device, and
the Doppler frequency shift information is Doppler frequency shift information associated with motion of a sensing target in a channel.
